(19) United States
(12) Patent Application Publication
(10) Pub. No.: US 2026/0323923 A1
(43) Pub. Date: Oct. 15, 2026

(54) SEMICONDUCTOR DEVICE INCLUDING ACTIVE STRUCTURE

(71) Applicant: SAMSUNG ELECTRONICS CO., LTD., Suwon-si (KR)

(72) Inventors: Gyunghyun YOON, Suwon-si (KR); Youngwoo KIM, Suwon-si (KR)

(73) Assignee: SAMSUNG ELECTRONICS CO., LTD., Suwon-si (KR)

(21) Appl. No.: 19/646,074

(22) Filed: Apr. 13, 2026

(30) Foreign Application Priority Data
Apr. 14, 2025 (KR) 10-2025-0048441

(51) Int. Cl. H10B 12/00

(52) U.S. Cl. CPC H10B 12/482; H10B 12/0335; H10B 12/315

(57) ABSTRACT

A semiconductor device includes an active structure, a gate structure, a bit line structure, a contact plug structure, and a capacitor. The active structure includes an active pattern on a substrate and extending in a first direction, and an epitaxial pattern on a sidewall of each of opposite end portions in the first direction of the active pattern. A lowermost surface of the epitaxial pattern is substantially coplanar with a lower surface of the active pattern, and the epitaxial pattern includes a single crystalline semiconductor material. The gate structure is disposed in a recess extending through a portion of an upper portion of the active structure. The bit line structure is disposed on a central portion of the active structure in the first direction. The contact plug structure is disposed on each of opposite end portions of the active structure. The capacitor is disposed on the contact plug structure.

### CROSS-REFERENCE TO RELATED APPLICATION

This application claims priority under 35 U.S.C. § 119 to Korean Patent Application No. 10-2025-0048441 filed on Apr. 14, 2025 in the Korean Intellectual Property Office, the disclosure of which is hereby incorporated by reference in its entirety.

### TECHNICAL FIELD

Example embodiments of the present disclosure relate to a gate structure and a method of forming the same, a semiconductor device including the gate structure and a method of manufacturing the same.

### DISCUSSION OF RELATED ART

A DRDM device includes an active pattern extending in a direction on a substrate, and a contact plug structure is disposed between and electrically connects a source/drain region in the active pattern and a capacitor. Thus, a connection state between the contact plug structure and the active pattern affects electric characteristics of the DRAM device.

### SUMMARY

Example embodiments provide a semiconductor device.

According to example embodiments of the inventive concepts, there is provided a semiconductor device. The semiconductor device may include at least one active structure, a gate structure, a bit line structure, a contact plug structure, and a capacitor. The at least one active structure may include an active pattern disposed on a substrate and extending in a first direction parallel to an upper surface of the substrate, and an epitaxial pattern on a sidewall of each of opposite end portions in the first direction of the active pattern. A lowermost surface of the epitaxial pattern may be substantially coplanar with a lower surface of the active pattern, and the epitaxial pattern may include a single crystalline semiconductor material. The gate structure may be disposed in a recess extending through a portion of an upper portion of the at least one active structure. The bit line structure may be disposed on a central portion of the at least one active structure in the first direction. The contact plug structure may be disposed on each of the opposite end portions of the at least one active structure. The capacitor may be disposed on the contact plug structure.

According to example embodiments of the inventive concepts, there is provided a semiconductor device. The semiconductor device may include active structures, a gate structure, a bit line structure, a contact plug structure, and a capacitor. The active structures may include active patterns and epitaxial patterns. The active patterns may be disposed on a substrate, and each of the active patterns may extend in a first direction parallel to an upper surface of the substrate and including first sidewalls opposite to each other in the first direction and second sidewalls opposite to each other in a second direction parallel to the upper surface of the substrate and perpendicular to the first direction. Each of the first sidewalls may have a curved shape and each of the second sidewalls may have a shape of a line extending in the first direction in a plan view. The active patterns may be disposed in a third direction parallel to the upper surface of the substrate and having an acute angle with respect to each of the first and second directions. The epitaxial patterns may be disposed on the first sidewalls, respectively, of each of the active patterns. The gate structure may be disposed in a recess respectively extending through portions of upper portions of the active structures. The bit line structure may be disposed on a central portion of each of the active structures in the first direction. The contact plug structure may be disposed on each of opposite end portions in the first direction of each of the active structures. The capacitor may be disposed on the contact plug structure. The epitaxial patterns on the first sidewalls, respectively, of one of the active patterns may not overlap each other in the third direction.

According to example embodiments of the inventive concepts, there is provided a semiconductor device. The semiconductor device may include an active structure, an isolation pattern, a gate structure, a bit line structure, a contact plug structure, and a capacitor. The active structure may include an active pattern and an epitaxial pattern. The active pattern may be disposed on a substrate, and may extend in a first direction parallel to an upper surface of the substrate. The active pattern may include first sidewalls opposite to each other in the first direction and second sidewalls opposite to each other in a second direction parallel to the upper surface of the substrate and perpendicular to the first direction. Each of the first sidewalls may have a curved shape and each of the second sidewalls may have a shape of a line extending in the first direction in a plan view. The epitaxial pattern may be disposed on each of the first sidewalls of the active pattern. A lowermost surface of the epitaxial pattern may be substantially coplanar with a lower surface of the active pattern, and the epitaxial pattern may include a single crystalline semiconductor material. The isolation pattern may be disposed on the substrate and may cover the second sidewalls of the active pattern and a sidewall of the epitaxial pattern. The gate structure may be disposed in a recess extending through a portion of an upper portion of the active structure. The bit line structure may be disposed on a central portion of the active structure in the first direction. The contact plug structure may be disposed on each of opposite end portions in the first direction of the active structure. The capacitor may be disposed on the contact plug structure.

The active structure of the semiconductor device may have an increased area, and thus a contact area between the active structure and the contact plug structure may increase to reduce a contact resistance therebetween. Accordingly, the semiconductor device may have enhanced electric characteristics.

### BRIEF DESCRIPTION OF THE DRAWINGS

FIG. 1 is a plan view illustrating a semiconductor device in accordance with example embodiments, FIG. 2 is a cross-sectional view taken along line A-A′ of FIG. 1, and FIG. 3 is a perspective view illustrating a first active structure included in the semiconductor device.

FIGS. 4 to 26 are perspective views, plan views and cross-sectional views illustrating a method of manufacturing a semiconductor device in accordance with example embodiments, in which FIGS. 4, 5, 6, 7, 8, and 9 are the perspective views, FIGS. 10, 13, 16, 20 and 24 are the plan views, FIGS. 11, 14, 15, 17, 18, 19, 21, 22, 23, 25, and 26 are cross-sectional views taken along lines A-A′ of corresponding plan views, respectively, and FIG. 12 is a cross-sectional view taken along line B-B′ of FIG. 10.

FIGS. 27, 28, and 29 are a plan view and cross-sectional views illustrating a semiconductor device in accordance with example embodiments.

FIG. 30 is a perspective view illustrating a second active structure included in the semiconductor device.

FIGS. 31 to 73 are perspective views, plan views and cross-sectional views illustrating a method of manufacturing a semiconductor device in accordance with example embodiments, in which FIGS. 31, 32, and 33 are the perspective views, FIGS. 34, 37, 40, 43, 46, 49, 52, 55, 62, 65, 68 and 71 are the plan views, each of FIGS. 35, 38, 41, 44, 47, 50, 53, 56, 58, 60, 63, 66, 69 and 72 includes cross-sectional views taken along lines A-A′ and B-B′, respectively, of a corresponding plan view, and each of FIGS. 36, 39, 42, 45, 48, 51, 54, 57, 59, 61, 64, 67, 70 and 73 includes cross-sectional views taken along lines C-C′ and E-E′, respectively, of a corresponding plan view, and FIGS. 31, 32, and 33 are perspective views of region Y of FIG. 34.

### DETAILED DESCRIPTION

The above and other aspects and features of a semiconductor device and a method of manufacturing the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

Hereinafter, two directions among horizontal directions that are substantially parallel to an upper surface of a first substrate or a second substrate, which may be substantially perpendicular to each other, may be referred to as first and second directions D1 and D2, respectively, a direction among the horizontal direction, which may have an acute angle with respect to the first and second directions D1 and D2, may be referred to as a third direction D3, and a direction among the horizontal direction, which may be substantially perpendicular to the third direction D3 may be referred to as a fourth direction D4. The fourth direction D4 may also have an acute angle with respect to the first and second directions D1 and D2. A direction substantially perpendicular to the upper surface of the first substrate or the second substrate may be referred to as a fifth direction D5.

Each of the first to fifth directions D1, D2, D3, D4 and D5 may include not only a direction shown in the drawings but also a direction opposite thereto.

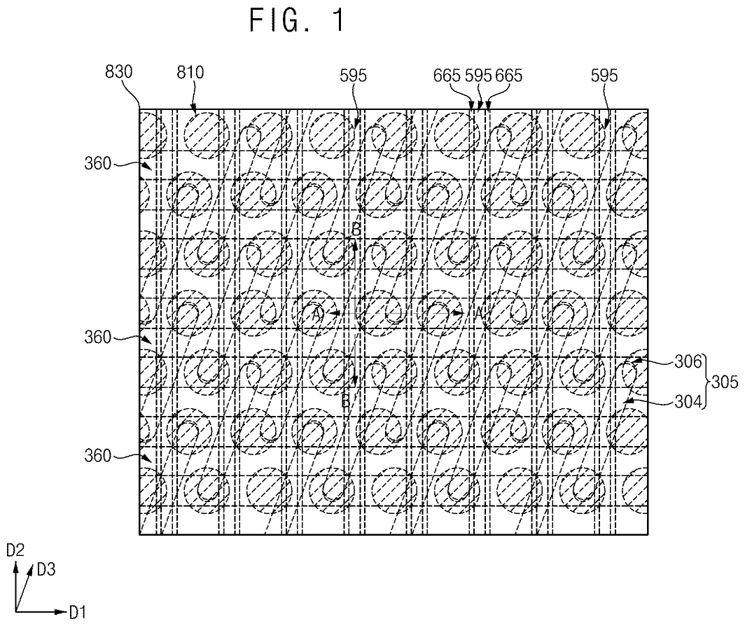

FIG. 1 is a plan view illustrating a semiconductor device in accordance with example embodiments, FIG. 2 is a cross-sectional view taken along line A-A′ of FIG. 1, and FIG. 3 is a perspective view illustrating a first active structure included in the semiconductor device.

Referring to FIGS. 1 to 3, the semiconductor device may include a first active structure 305, a first gate structure 360, a first bit line structure 595, a first contact plug structure and a first capacitor 840.

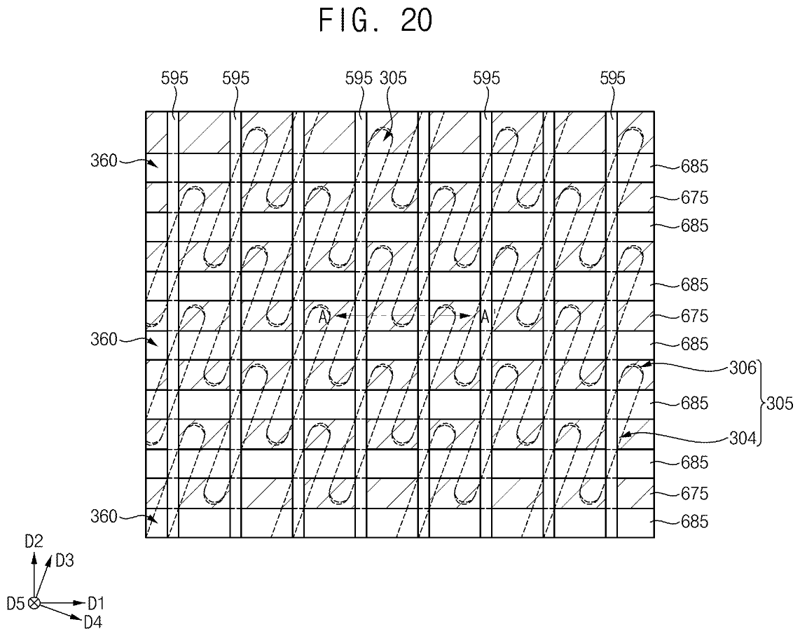

The semiconductor device may further include a first isolation pattern 310, a first spacer structure 665, a fourth spacer 690, a first fence pattern 685 (refer to FIG. 20), first and second insulation pattern structures 435 and 790, fourth and fifth insulation patterns 610 and 620, a metal silicide pattern 700, and a second etch stop layer 800.

The first active structure 305 may be disposed on a first substrate 300.

The first substrate 300 may include a semiconductor material, e.g., silicon, germanium, silicon-germanium, etc., or a III-V group compound semiconductor, e.g., GaP, GaAs, GaSb, etc. In example embodiments, the first substrate 300 may be a silicon-on-insulator (SOI) substrate or a germanium-on-insulator (GOI) substrate.

The first active structure 305 may include a first active pattern 304 and a first epitaxial pattern 306. In example embodiments, the first active structure 305 may extend in the third direction D3 to a given length on the first substrate 300, and a plurality of first active structures 305 may be spaced apart from each other in the third direction D3. Additionally, a plurality of first active structures 305 may be spaced apart from each other in the first direction D1 or the fourth direction D4, and the first active structures 305 may be disposed in a zigzag pattern in the first direction D3. That is, end portions of ones of the first active structures 305 disposed in the first direction D1 may not be aligned with each other in the first direction D1.

The first active pattern 304 included in each of the first active structures 305 may extend in the third direction D3 to a given length. An extension length in the third direction D3 of the first active pattern 304 may be greater than a width in the fourth direction D4 of the first active pattern 304. In example embodiments, a sidewall of each of opposite end portions in the third direction D3 of the active pattern 304 may have a curve, e.g., a rounded shape in a plan view.

In example embodiments, the extension lengths in the third direction D3 of the first active patterns 304 may be substantially the same as each other, and the widths in the fourth direction D4 of the first active patterns 304 may be substantially the same as each other. The first active pattern 304 may include a material substantially the same as that of the first substrate 300.

The first epitaxial pattern 306 may be disposed on the sidewall of each of the end portions in the third direction D3 of the active pattern 304. In example embodiments, each of the first active patterns 304 may include first sidewalls 301 opposite to each other in the third direction D3 and second sidewalls 303 opposite to each other in the fourth direction D4, and the first epitaxial pattern 306 may be disposed on each of the first sidewalls 301 of each of the first active patterns 304. Each of the first sidewalls 301 of each of the first active patterns 304 may have a linear shape extending in the third direction D3 in a plan view, and each of the second sidewalls 303 of each of the first active patterns 304 may have a curved shape, e.g., rounded shape in a plan view.

In example embodiments, the first epitaxial patterns 306 on the first sidewalls 301, respectively, of each of the first active patterns 304 may overlap each other neither in the first direction D1 nor in the fourth direction D4.

In an example embodiment, the first epitaxial pattern 306 may have a constant thickness on the sidewall of each of opposite end portions in the third direction D3 of the first active pattern 304, however, the inventive concept is not limited thereto. Each of opposite end portions in the third direction D3 of the first active structure 305 including the first active pattern 304 and the first epitaxial pattern 306 may have a curved shape, e.g., a rounded shape in a plan view.

In example embodiments, an uppermost surface of the first epitaxial pattern 306 may be substantially coplanar with an upper surface of the first active pattern 304, and a lowermost surface of the first epitaxial pattern 306 may be substantially coplanar with a lower surface of the first active pattern 304. The expression “substantially coplanar” or the like may mean that the terms being described are coplanar with each other, or the two terms being described are almost on a same plane but with some variation due to an unperfect process or a margin, an error, or a tolerance in manufacturing or measurement. Such a margin, an error, or a tolerance may occur in manufacturing or measurement, recognized by those of skill in the art. In one or more aspects, it may indicate an industry-accepted tolerance or margin, such as ±1%, ±5%, or ±10%, between heights of the terms being described with respect to a reference plane, for example, a lower surface of the first substrate 300.

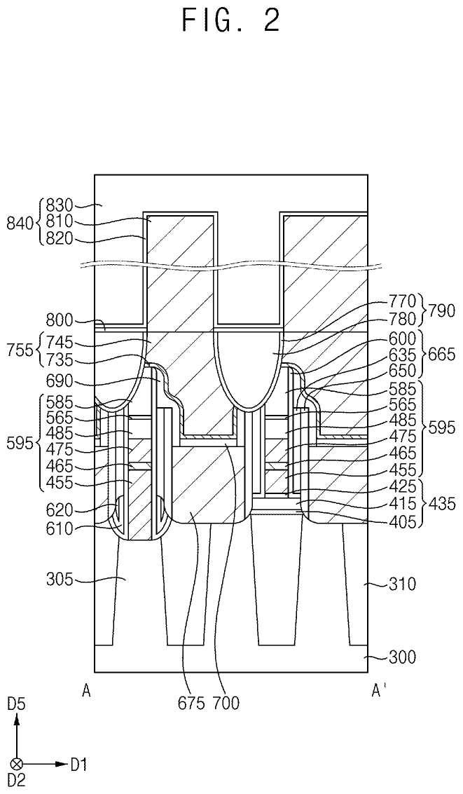

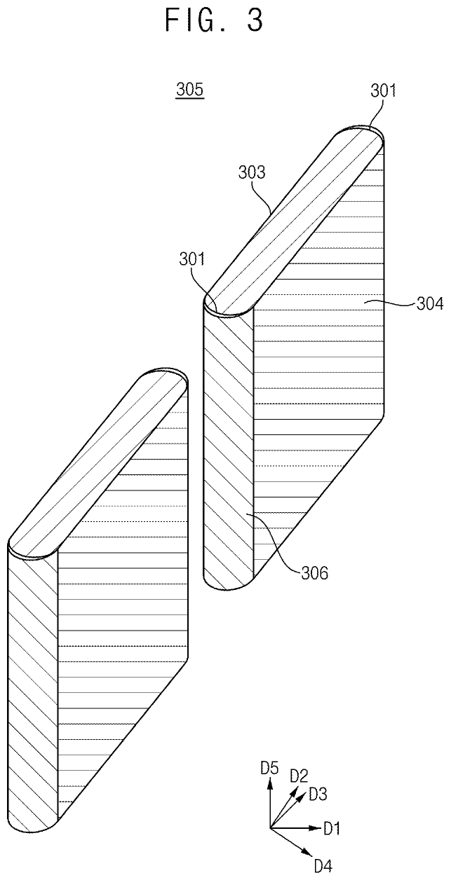

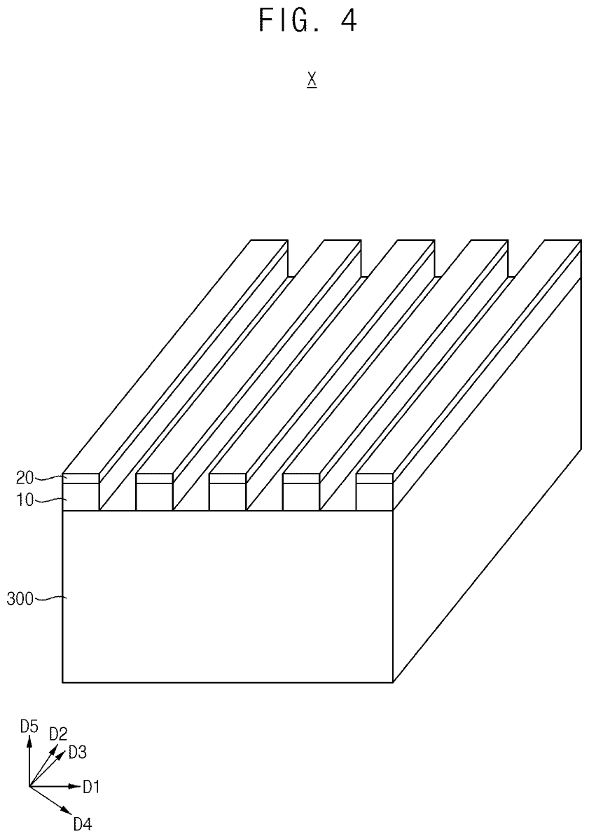

In example embodiments, the first epitaxial pattern 306 may include a single crystalline semiconductor material, e.g., single crystalline silicon, single crystalline germanium, etc. As illustrated below with respect to FIGS. 4 to 26, the first epitaxial pattern 306 may be formed by a selective epitaxial growth (SEG) process using the sidewall of the first active pattern 304 as a seed, so that the first epitaxial pattern 306 may include a material substantially the same as that of the first active pattern 304. The expression “material being substantially the same as” or the like may mean that the materials being described are the same as each other, or the materials being described contain almost the same material but with some variation in impurity or crystal orientation due to an unperfect process or a margin, an error, or a tolerance in manufacturing or measurement. Such a margin, an error, or a tolerance may occur in manufacturing or measurement, recognized by those of skill in the art. In one or more aspects, it may indicate an industry-accepted tolerance or difference, such as ±1%, ±5%, or ±10%, in impurity and/or crystal orientation between the materials being described.

In an example embodiment, a crystalline orientation of the first epitaxial pattern 306 may be different from that of the first active pattern 304, and thus the first epitaxial pattern 306 and the first active pattern 304 may be distinguished from each other. Alternatively, the crystalline orientation of the first epitaxial pattern 306 may be substantially the same as that of the first active pattern 304, and thus the first epitaxial pattern 306 and the first active pattern 304 may not be distinguished from each other. The expression “the crystalline orientation being substantially the same as” or the like may mean that the materials being described have the same crystalline orientation, or the materials being described contain almost the same crystalline orientation but with some variation due to an unperfect process or a margin, an error, or a tolerance in manufacturing or measurement. Such a margin, an error, or a tolerance may occur in manufacturing or measurement, recognized by those of skill in the art. In one or more aspects, it may indicate an industry-accepted tolerance or difference, such as ±1%, ±5%, or ±10%, in crystal orientation between the materials being described.

In an example embodiment, the first epitaxial patterns 306 may have the same crystalline orientation. Alternatively, the first epitaxial patterns 306 may have different crystalline orientations from each other.

If some ones of the first epitaxial patterns 306 disposed on sidewalls of first ones of the first active patterns 304 have the same crystalline orientation as that of the first ones of the first active patterns 304 so as to be merged thereto, and other ones of the first epitaxial patterns 306 disposed on sidewalls of second ones of the first active patterns 304 have different crystalline orientations from that of the second ones of the first active patterns 304 so as to be distinguished therefrom, extension lengths in the third direction D3 of the first ones of the first active patterns 304 including the first epitaxial patterns 306 merged thereto may be greater than extension lengths in the third direction D3 of the second ones of the first active patterns 304 not including the first epitaxial patterns 306.

The first isolation pattern 310 may be disposed on the first substrate 300, and may cover a sidewall of the first active structure 305.

Particularly, the first isolation pattern 310 may contact and cover an upper surface of a portion of the first substrate 300 on which the first active structure 305 is not disposed, and may contact and cover opposite sidewalls in the fourth direction D4 of the first active pattern 304 included in each of the first active structures 305. Additionally, the first isolation pattern 310 may contact and cover a sidewall of the first epitaxial pattern 306 included in each of the first active structures 305.

In example embodiments, an upper surface of the first isolation pattern 310 may be substantially coplanar with an upper surface of the first active structure 305, and a lower surface of the first isolation pattern 310 may be substantially coplanar with a lower surface of the first active structure 305.

The first isolation pattern 310 may include an oxide, e.g., silicon oxide.

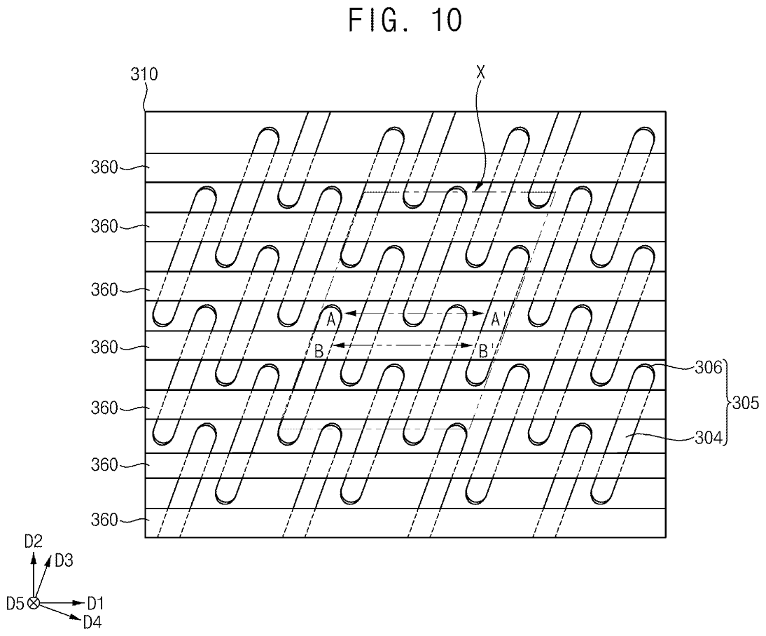

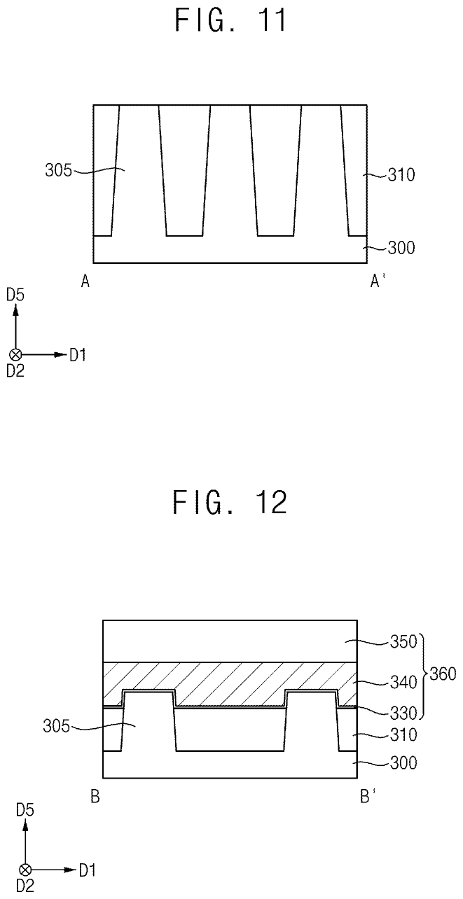

Referring to FIGS. 1 to 3 together with FIG. 12, the first gate structure 360 may be disposed in a second recess extending through upper portions of the first active structure 305 and the first isolation pattern 310 in the second direction. In example embodiments, the first gate structure 360 may extend in the first direction D1, and a plurality of first gate structures 360 may be spaced apart from each other in the second direction D2.

The first gate structure 360 may include a first gate electrode 340 and a first gate mask 350 stacked in the fifth direction D5, and a first gate insulation pattern 330 covering sidewalls of the first gate electrode 340 and the first gate mask 350.

The first gate electrode 340 may include, e.g., a metal, a metal nitride, a metal silicide, doped polysilicon, etc., the first gate mask 350 may include an insulating nitride, e.g., silicon nitride, and the first gate insulation pattern 330 may include an oxide, e.g., silicon oxide.

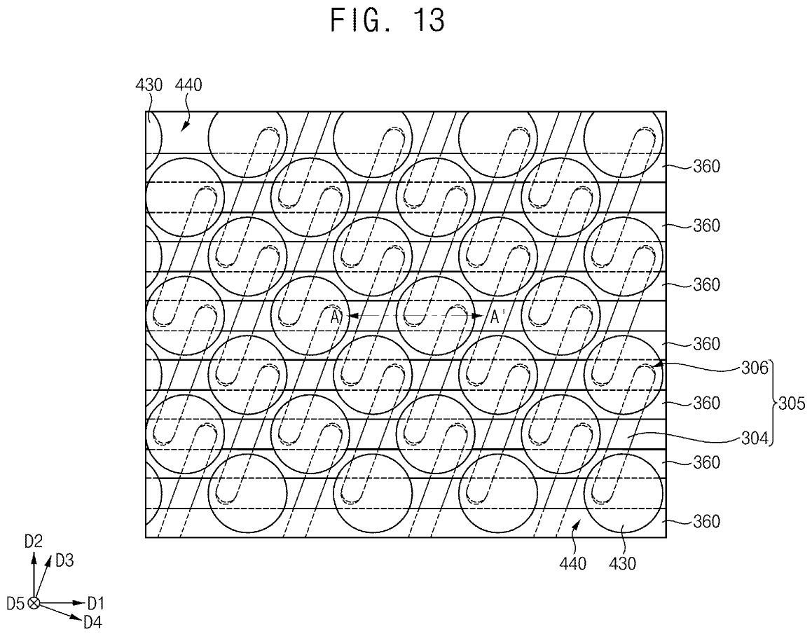

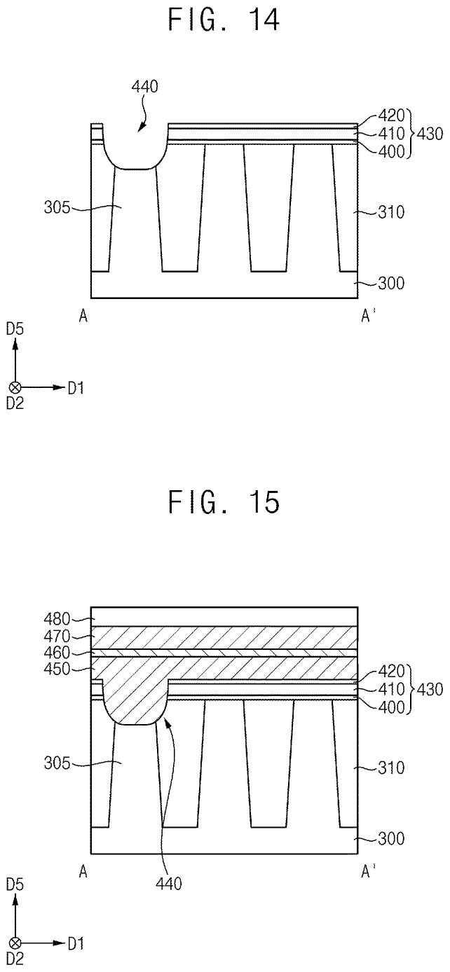

Referring to FIGS. 1 to 3 together with FIGS. 13 and 14, a third opening 440 extending through an insulation layer structure 430 and exposing upper surfaces of the first active structure 305, the first isolation pattern 310, the first gate mask 350 and the first gate insulation pattern 330 may be formed, and an upper surface of a central portion in the third direction D3 of the first active structure 305 may be exposed by the third opening 440.

In example embodiments, a bottom of the third opening 440 may be wider than the upper surface of the central portion in the third direction D3 of the first active structure 305 exposed by the third opening 440. Thus, the third opening 440 may also expose an upper surface of a portion of the first isolation pattern 310 adjacent to the first active structure 305. Additionally, the third opening 440 may extend through an upper portion of the first active structure 305 and an upper portion of the first isolation pattern 310 adjacent thereto, and thus the bottom of the third opening 440 may be lower than an upper surface of a portion of the first active structure 305 on which the first opening 440 is not formed, that is, an upper surface of an end portion in the third direction D3 of the first active structure 305.

The first bit line structure 595 may include a first conductive pattern 455, a first barrier pattern 465, a second conductive pattern 475, a fifth mask 485, a first etch stop pattern 565 and a capping pattern 585 sequentially stacked in the fifth direction D5 on the third opening 440 or on the first insulation pattern structure 435. The first conductive pattern 455, the first barrier pattern 465 and the second conductive pattern 475 may collectively form a conductive structure, and the fifth mask 485, the first etch stop pattern 565 and the capping pattern 585 may collectively form an insulation structure.

The first conductive pattern 455 may include, e.g., doped polysilicon, the first barrier pattern 465 may include a metal nitride, e.g., titanium nitride, or a metal silicon nitride, e.g., titanium silicon nitride, the second conductive pattern 475 may include a metal, e.g., tungsten, and each of the fifth mask 485, the first etch stop pattern 565 and the capping pattern 585 may include an insulating nitride, e.g., silicon nitride.

In example embodiments, the first bit line structure 595 may extend in the second direction D2 on the first substrate 300, and a plurality of first bit line structures 595 may be spaced apart from each other in the first direction D1.

The fourth and fifth insulation patterns 610 and 620 may be disposed in the third opening 440, and may contact a lower sidewall of the first bit line structure 595. The fourth insulation pattern 610 may include an oxide, e.g., silicon oxide, and the fifth insulation pattern 620 may include an insulating nitride, e.g., silicon nitride.

The first insulation pattern structure 435 may be disposed under the first bit line structure 595 on the first active structure 305 and the first isolation pattern 310, and may include first, second and third insulation patterns 405, 415 and 425 sequentially stacked in the fifth direction D5. The first and third insulation patterns 405 and 425 may include an oxide, e.g., silicon oxide, and the second insulation pattern 415 may include an insulating nitride, e.g., silicon nitride.

The first contact plug structure may include a lower contact plug 675, a metal silicide pattern 700 and an upper contact plug 755 sequentially stacked on the first active structure 305 and the first isolation pattern 310 in the fifth direction D5.

The lower contact plug 675 may contact the upper surface of each of opposite end portions in the third direction D3 of the first active structure 305. Particularly, the lower contact plug 675 may contact an upper surface of an end portion in the third direction D3 of the first active pattern 304 included in the first active structure 305 and an upper surface of the first epitaxial pattern 306 on the sidewall of the first active pattern 304.

Thus, when compared to a case in which the first active structure 305 includes only the first active pattern 304 and does not include the first epitaxial pattern 306, the lower contact plug 675 may contact an increased area with the upper surface of the first active structure 305, and a contact resistance between the first active structure 305 and the lower contact plug 675 may increase.

In example embodiments, a plurality of lower contact plugs 675 may be spaced apart from each other in the second direction D2 between neighboring ones of the first bit line structures 595 in the first direction D1.

The lower contact plug 675 may include, e.g., doped polysilicon, and the metal silicide pattern 700 may include, e.g., titanium silicide, cobalt silicide, nickel silicide, etc.

The first fence pattern 685 may be disposed between neighboring ones of the lower contact plugs 675 in the second direction D2, which may be spaced apart from each other by the first fence pattern 685. The first fence pattern 685 may include an insulating nitride, e.g., silicon nitride.

The upper contact plug 755 may include a second metal pattern 745 and a second barrier pattern 735 covering a lower surface of the second metal pattern 745. The second metal pattern 745 may include a metal, e.g., tungsten, and the second barrier pattern 735 may include a metal nitride, e.g., titanium nitride.

In example embodiments, a plurality of upper contact plugs 755 may be spaced apart from each other in each of the first and second directions D1 and D2, and may be arranged in a honeycomb pattern or a lattice pattern in a plan view. Each of the upper contact plugs 755 may have a shape of, e.g., a circle, an ellipse or a polygon in a plan view.

The first spacer structure 665 may include a first spacer 600 covering a sidewall of the first bit line structure 595 and a sidewall of the third insulation pattern 425, an air spacer 635 on a lower outer sidewall of the first spacer 600, and a third spacer 650 covering an outer sidewall of the air spacer 635, a sidewall of the first insulation pattern structure 435 and upper surfaces of the fourth and fifth insulation patterns 610 and 620.

Each of the first and third spacers 600 and 650 may include an insulating nitride, e.g., silicon nitride, and the air spacer 635 may include air.

The fourth spacer 690 may be disposed on an outer sidewall of a portion of the first spacer 600 on an upper sidewall of the first bit line structure 595, and may cover a top of the air spacer 635 and an upper surface of the third spacer 650. The fourth spacer 690 may include an insulating nitride, e.g., silicon nitride.

Referring to FIGS. 1 to 3 together with FIGS. 24 and 25, the second insulation pattern structure 790 may include a sixth insulation pattern 770 and a seventh insulation pattern 780. The sixth insulation pattern 770 may be disposed on an inner wall of an eighth opening 760 extending through the upper contact plug 755, a portion of the insulation structure included in the first bit line structure 595, and portions of the first, third and fourth spacers 600, 650 and 690 to surround the upper contact plug 755 in a plan view. The seventh insulation pattern 780 may be disposed on the sixth insulation pattern 770, and may fill a remaining portion of the eighth opening 760. The top of the air spacer 635 may be closed by the sixth insulation pattern 770.

The sixth and seventh insulation patterns 770 and 780 may include an insulating nitride, e.g., silicon nitride.

The second etch stop layer 800 may be disposed on the sixth and seventh insulation patterns 770 and 780, the upper contact plug 755 and the first fence pattern 685.

The first capacitor 840 may include a first lower electrode 810, a first dielectric layer 820 and a first upper electrode 830 sequentially stacked. The first lower electrode 810 may extend through the second etch stop layer 800, and may contact an upper surface of the upper contact plug 755.

As illustrated above, the semiconductor device may include the first active structure 305, which may include the first active pattern 304, and the first epitaxial pattern 306 on each of opposite end portions in the third direction D3 of the first active pattern 304. Thus, when compared to a case in which the first active structure 305 does not include the first epitaxial pattern 306, each of the end portions in the third direction D3 of the first active structure 305 including the first epitaxial pattern 306 may have an increased area, so that a contact area between the lower contact plug 675 and the first active structure 305 may increase to reduce a contact resistance therebetween.

Accordingly, an electric connection between a source/drain region in the first active structure 305 and the first capacitor 840, which may be electrically connected to the source/drain region through the first contact plug structure including the lower contact plug 675 may be enhanced, and the semiconductor device including the first active structure 305 and the first capacitor 840 may have improved electrical characteristics.

FIGS. 4 to 26 are perspective views, plan views and cross-sectional views illustrating a method of manufacturing a semiconductor device in accordance with example embodiments. Particularly, FIGS. 4 to 9 are the perspective views of region X of FIG. 10, FIGS. 10, 13, 16, 20 and 24 are the plan views, FIGS. 11, 14-15, 17-19, 21-23 and 25-26 are cross-sectional views taken along lines A-A′ of corresponding plan views, respectively, and FIG. 12 is a cross-sectional view taken along line B-B′ of FIG. 10.

Referring to FIG. 4, a first pad layer and a first mask layer may be sequentially formed on a first substrate 300, and an etching process may be performed on the first mask layer and the first pad layer to form a first mask 20 and a first pad 10, respectively.

In example embodiments, each of the first mask 20 and the first pad 10 may extend in the third direction D3, and a plurality of first masks 20 may be formed to be spaced apart from each other in the first direction D1 and a plurality of first pads 10 may be formed to be spaced apart from each other in the first direction D1.

The first pad 10 may include an oxide, e.g., silicon oxide, and the first mask 20 may include a semiconductor material, e.g., polysilicon, however, the inventive concept is not limited thereto.

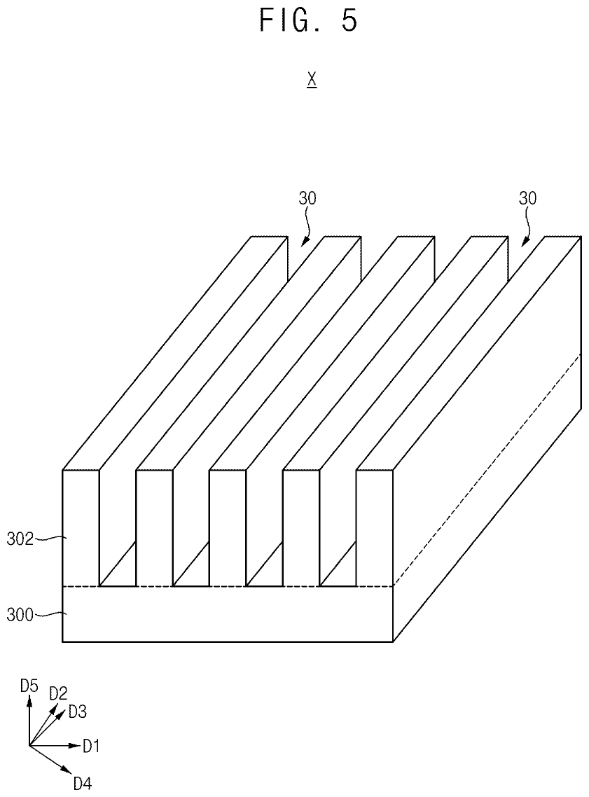

Referring to FIG. 5, an etching process may be performed using the first mask 20 and the first pad 10 as an etching mask to form a first recess 30 on the first substrate 300.

In example embodiments, the first recess 30 may extend in the third direction D3, and a plurality of first recesses 30 may be formed to be spaced apart from each other in the first direction D1.

As the first recesses 30 are formed, a first preliminary active patterns 302 may be formed to be spaced apart from each other in the first direction D1 by the first recesses 30 on the first substrate 300, and each of the first preliminary active patterns 302 may extend in the third direction D3.

Referring to FIG. 6, a first preliminary isolation layer 40 may be formed on the first substrate 300 and the first preliminary active patterns 302 to fill the first recesses 30, and second and third mask layers 50 and 60 may be sequentially formed on the first preliminary isolation layer 40.

The second mask layer 50 may include, e.g., spin-on-hardmask (SOH), amorphous carbon layer (ACL), etc., and the third mask layer 60 may include, e.g., plasma enhanced silicon oxynitride (PE-SiON), however, the inventive concept is not limited thereto.

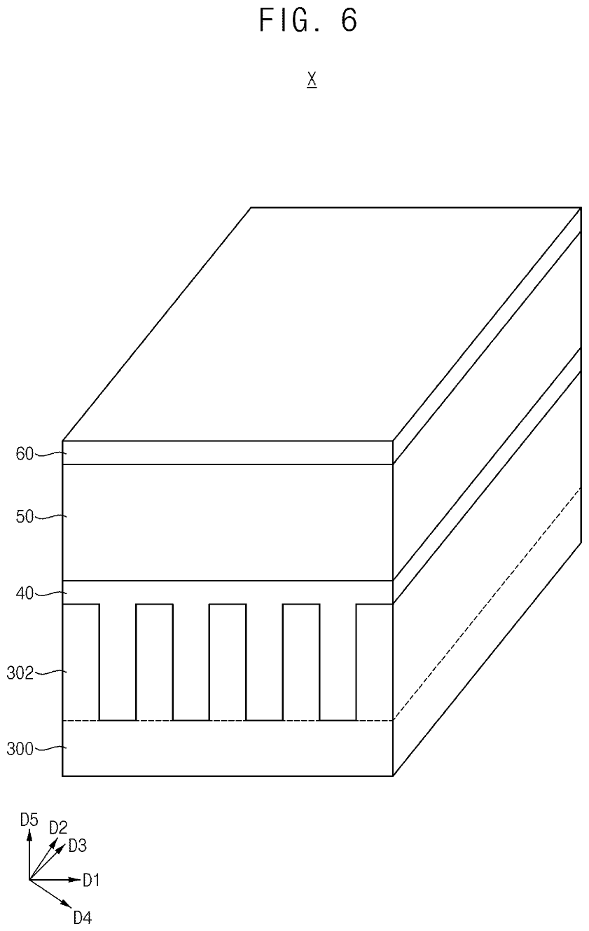

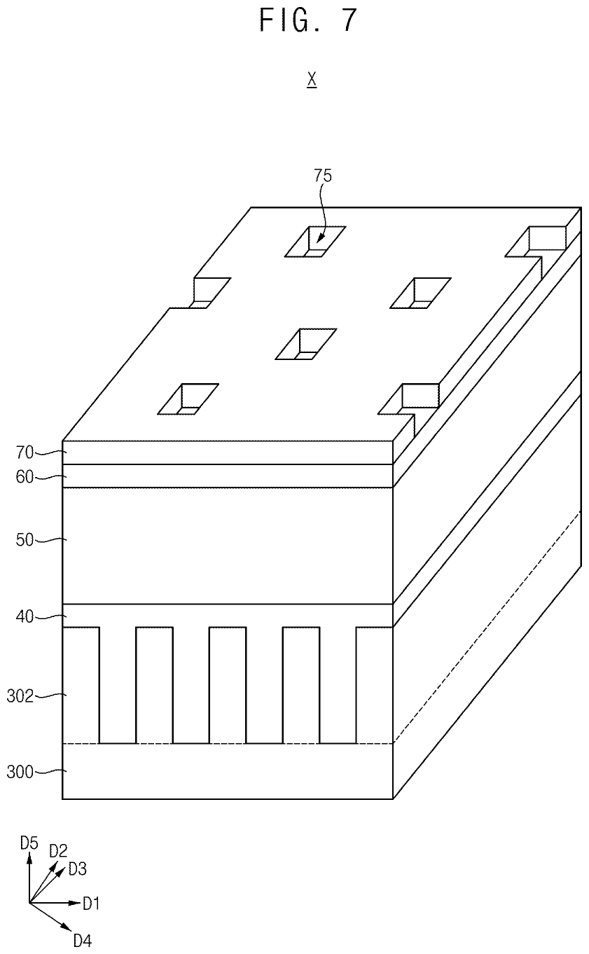

Referring to FIG. 7, a fourth mask layer 70 may be formed on the third mask layer 60, and the fourth mask layer 70 may be partially removed to form a first opening 75 exposing an upper surface of the third mask layer 60.

The fourth mask layer 70 may include, e.g., photoresist layer, and the fourth mask layer 70 may be partially removed by, e.g., a photolithography process.

In example embodiments, the first opening 75 may overlap the first preliminary active pattern 302 in the fifth direction D5, and a plurality of first openings 75 may be formed to be spaced apart from each other in the third direction D3 on each of the first preliminary active patterns 302. Thus, a plurality of first openings 75 may be formed to be spaced apart from each other in each of the first and third direction D1 and D3, and some of the first openings 75 may overlap each other in the first direction D1.

Each of the first openings 75 may have a shape of, e.g., a rectangle, a rectangle with rounded corners, a circle, an ellipse, etc., in a plan view.

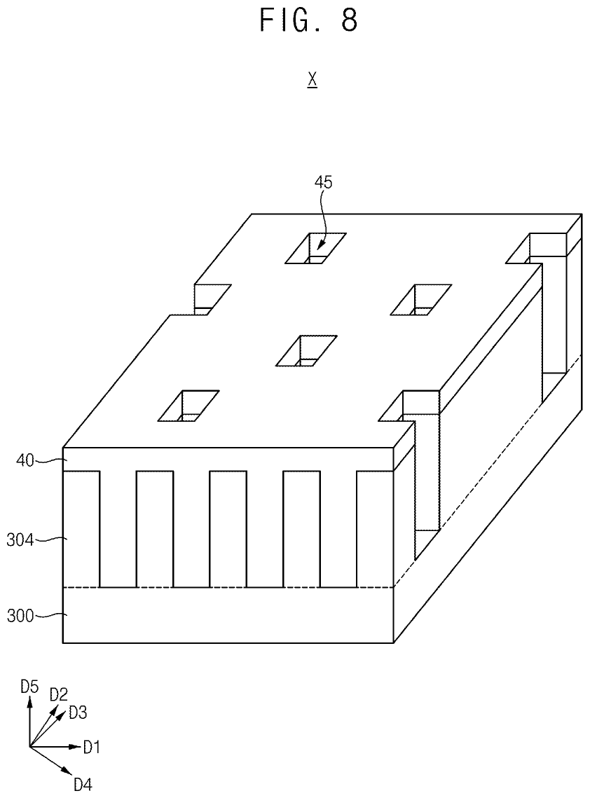

Referring to FIG. 8, for example, a dry etching process may be performed on a structure on the first substrate 300.

As the dry etching process is performed, the second to fourth mask layers 50, 60 and 70 may be removed, and a portion of the first preliminary isolation layer 40 overlapping the first opening 75 in the fifth direction D5 and a portion of the first preliminary active pattern 302 thereunder may be removed to form a second opening 45 exposing the upper surface of the first substrate 300.

The second opening 45 may extend through each of the first preliminary active patterns 302 to expose the upper surface of the first substrate 300, and a plurality of second openings 45 may be formed to be spaced apart from each other in the third direction D3. Accordingly, each of the first preliminary active patterns 302 may be divided into a plurality of first active patterns 304 spaced apart from each other in the third direction D3 by the second openings 45.

In example embodiments, a plurality of first active patterns 304 may be formed to be spaced apart from each other in each of the first and third direction D1 and D3.

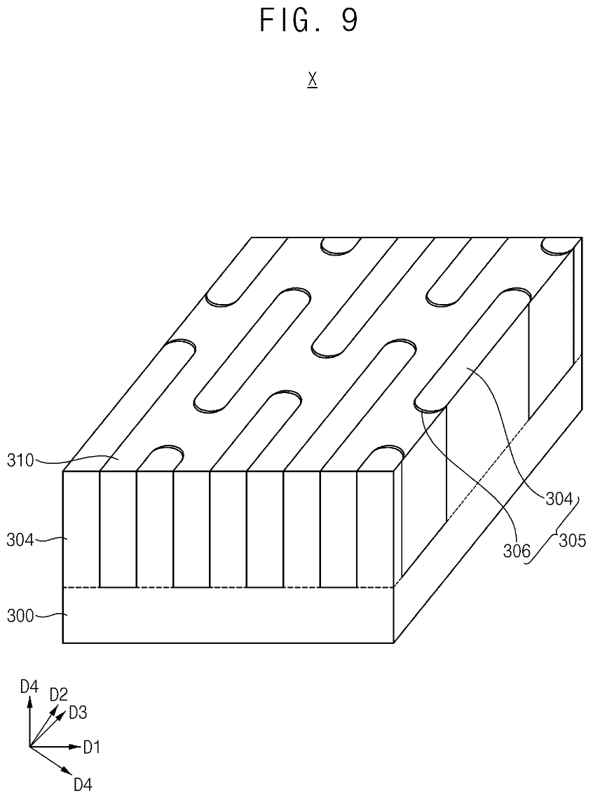

Referring to FIG. 9, a selective epitaxial growth (SEG) process may be performed using a sidewall of the first active pattern 304 exposed by the second opening 45 to form a first epitaxial pattern 306 on a portion of the first active pattern 304 exposed by the second opening 45.

In example embodiments, the first epitaxial pattern 306 may be formed on a sidewall of each of end portions in the third direction D3 of the first active pattern 304 exposed by the second opening 45.

In some embodiments, the first epitaxial pattern 306 may also be formed on the upper surface of the first substrate 300 exposed by the second opening 45, however, in this case, an anisotropic etching process may be further performed on the first epitaxial pattern 306 so that the first epitaxial pattern 306 on the upper surface of the first substrate 300 may be removed.

The second opening 45 may expose the end portions in the third direction D3 of the first active pattern 304 so as to define a region in which the first epitaxial pattern 306 is formed by the SEG process. That is, the first epitaxial pattern 306 may not be formed on, for example, each of opposite sidewalls in the fourth direction D4 of the first active pattern 304 not exposed by the second opening 45, and the first epitaxial pattern 306 may be formed only on each of opposite end portions in the third direction D3 of the first active pattern 304 exposed by the second opening 45.

For example, if an upper portion of the first substrate 300 is patterned by a single etching process to form a plurality of active patterns spaced apart from each other in each of the first and third directions D1 and D3 and a SEG process is performed, an epitaxial pattern may be formed on an entire portion of sidewalls of the active pattern, and thus the epitaxial pattern may not be formed on a specific portion, e.g., the end portions of the active pattern.

Additionally, the active patterns may be formed by the single etching process to be spaced apart from each other in each of the first and third directions D1 and D3, so that some of the active patterns may not be separated from each other to form a bridge.

However, in example embodiments, the first recesses 30 may be formed on the first substrate 300 to form the first preliminary active patterns 302, each of which may extend in the third direction D3, spaced apart from each other in the first direction D1, the first preliminary isolation layer 40 and the second to fourth mask layers 50, 60 and 70 may be sequentially formed to fill the first recesses 30, the fourth mask layer 70 may be partially removed to form the first opening 75 overlapping the first preliminary active pattern 302 in the fifth direction D5, and the dry etching process may be performed to form the second opening 45 extending through the first preliminary active pattern 302, so that the first preliminary active pattern 302 may be divided into the first active patterns 304.

Thus, only the sidewalls of the opposite end portions in the third direction D3 of each of the first active patterns 304 may be exposed by the second openings 45, and the first epitaxial patterns 306 may be formed on the exposed sidewalls of the opposite end portions in the third direction D3 of each of the first active patterns 304.

Additionally, after performing a first etching process on the upper portion of the first substrate 300 to form the first preliminary active patterns 302 spaced apart from each other in the first direction D1, and a second etching process may be performed to divide each of the first preliminary active patterns 302 into the first active patterns 304 spaced apart from each other in the third direction D3, so that a possibility of formation of the bridge between the first active patterns 304 may be reduced.

In an example embodiment, a crystalline orientation of the first epitaxial pattern 306 may be different from that of the first active pattern 304, and thus the first epitaxial pattern 306 may be distinguished from the first active pattern 304. Alternatively, the crystalline orientation of the first epitaxial pattern 306 may be substantially the same as that of the first active pattern 304, and thus the first epitaxial pattern 306 may not be distinguished from the first active pattern 304.

The first active pattern 304 and the first epitaxial pattern 306 may collectively form a first active structure 305. In example embodiments, the first active structure 305 may extend in the third direction D3, and a plurality of first active structures 305 may be spaced apart from each other in the first direction D1.

A second preliminary isolation layer may be formed on the first active structure 305 and the first preliminary isolation layer 40 to fill the second opening 45, and a planarization process may be performed on the second preliminary isolation layer until an upper surface of the first active pattern 304 is exposed.

In example embodiments, the planarization process may include, e.g., a chemical mechanical polishing (CMP) process and/or an etch back process.

In example embodiments, the second preliminary isolation layer may include a material substantially the same as that of the first preliminary isolation layer 40, so as to be merged thereto. By the planarization process, upper surfaces of the first preliminary isolation layer 40 and the second preliminary isolation layer may be substantially coplanar with the upper surface of the first active pattern 304, and the first preliminary isolation layer 40 and the second preliminary isolation layer may collectively form a first isolation pattern 310.

The first isolation pattern 310 may be formed on the first substrate 300, and may cover opposite sidewalls in the first direction D1 of each of the first active patterns 304. The first isolation pattern 310 may contact sidewalls of portions of the first epitaxial patterns 306 on opposite sidewalls, respectively, of the first active patterns 304 neighboring in the third direction D3.

Referring to FIGS. 10 to 12, the first active structure 305 and the first isolation pattern 310 may be partially removed to form a second recess extending in the first direction D1, and a first gate structure 360 may be formed in the second recess.

In example embodiments, the first gate structure 360 may extend in the first direction D1, and a plurality of first gate structures 360 may be spaced apart from each other in the second direction D2.

Referring to FIGS. 13 and 14, an insulation layer structure 430 may be formed on the first active structure 305, the first isolation pattern 310 and the first gate structure 360.

The insulation layer structure 430 may include first, second and third insulation layers 400, 410 and 420 sequentially stacked in the fifth direction D5.

The insulation layer structure 430 may be patterned, and the first active structure 305, the first isolation pattern 310, and upper portions of the first gate mask 350 and the first gate insulation pattern 330 of the first gate structure 360 may be partially etched by an etching process using the patterned insulation layer structure 430 as an etching mask to form a third opening 440. In example embodiments, the insulation layer structure 430 remaining after the etching process may have a shape of, e.g., a circle or an ellipse in a plan view, and a plurality of insulation layer structures 430 may be spaced apart from each other in each of the first and second directions D1 and D2. Each of the insulation layer structures 430 may overlap in the fifth direction D5 edge portions in the third direction D3 of neighboring first active structures 305, respectively.

Referring to FIG. 15, a first conductive layer 450, a first barrier layer 460, a second conductive layer 470 and a fifth mask layer 480 may be sequentially stacked on the insulation layer structure 430, and the first active structure 305, the first isolation pattern 310 and the first gate structure 360 exposed by the third opening 440, which may collectively form a conductive layer structure. The first conductive layer 450 may fill the third opening 440.

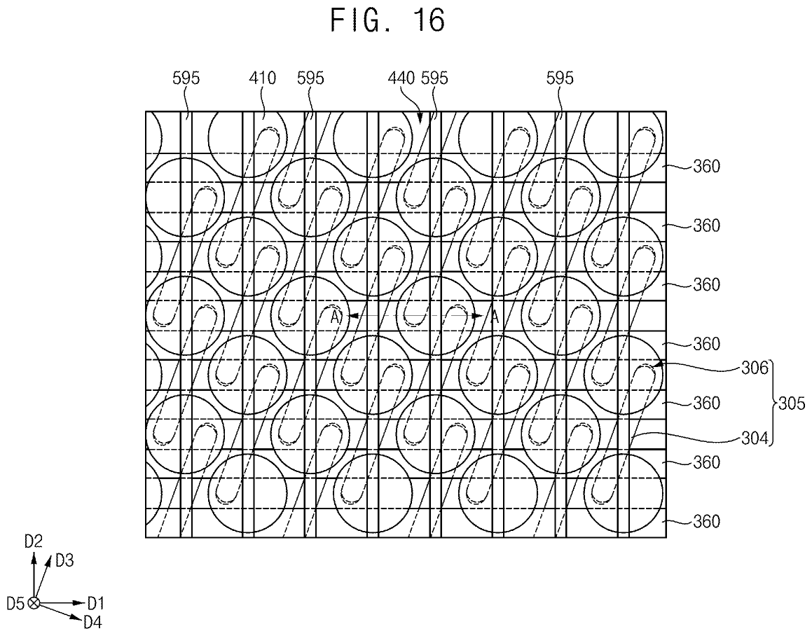

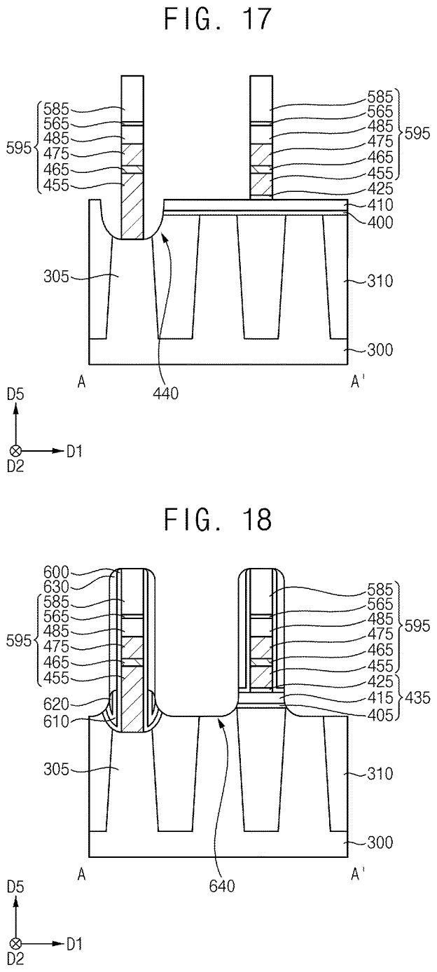

Referring to FIGS. 16 and 17, a first etch stop layer and a capping layer may be sequentially stacked on the conductive layer structure, and the capping layer may be etched to form a capping pattern 585.

The first etch stop layer, the fifth mask layer 480, the second conductive layer 470, the first barrier layer 460 and the first conductive layer 450 may be sequentially etched by an etching process using the capping pattern 585 as an etching mask.

In example embodiments, the capping pattern 585 may extend in the second direction D2, and a plurality of capping patterns 585 may be spaced apart from each other in the first direction D1.

By the etching process, a first conductive pattern 455, a first barrier pattern 465, a second conductive pattern 475, a fifth mask 485, a first etch stop pattern 565 and the capping pattern 585 may be sequentially stacked on the third opening 440, and a third insulation pattern 425, the first conductive pattern 455, the first barrier pattern 465, the second conductive pattern 475, the fifth mask 485, the first etch stop pattern 565 and the capping pattern 585 may be sequentially stacked on the second insulation layer 410 of the insulation layer structure 430 at an outside of the third opening 440.

Hereinafter, the first conductive pattern 455, the first barrier pattern 465, the second conductive pattern 475, the fifth mask 485, the first etch stop pattern 565 and the capping pattern 585 sequentially stacked may be referred to as a first bit line structure 595. The first conductive pattern 455, the first barrier pattern 465 and the second conductive pattern 475 may collectively form a conductive structure, and the fifth mask 485, the first etch stop pattern 565 and the capping pattern 585 may collectively form an insulation structure. In example embodiments, the first bit line structure 595 may extend in the second direction D2 on the first substrate 300, and a plurality of first bit line structures 595 may be spaced apart from each other in the first direction D1.

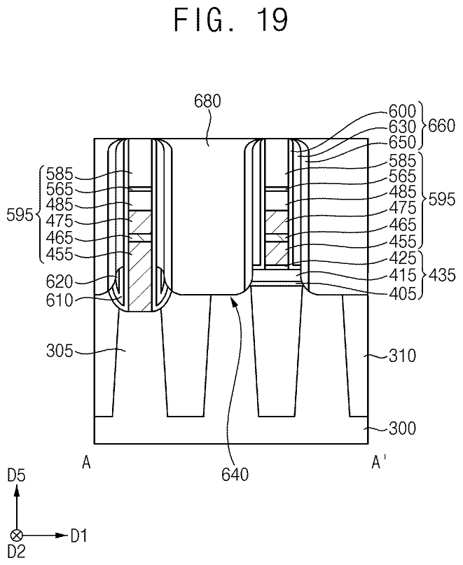

Referring to FIG. 18, a first spacer layer may be formed on the first substrate 300 having the first bit line structure 595 thereon, and fourth and fifth insulation layers may be sequentially formed on the first spacer layer.

The first spacer layer may also cover a sidewall of the third insulation pattern 425 under a portion of the first bit line structure 595 on the second insulation layer 410, and the fifth insulation layer may fill a remaining portion of the third opening 440.

The fourth and fifth insulation layers may be etched by an etching process. In example embodiments, the etching process may be performed by a wet etching process using an etching solution, e.g., H₂PO₃, SC1, HF, etc., and portions of the fourth and fifth insulation layers at the outside of the third opening 440 may be removed. Thus, a portion of the first spacer layer at the outside of the third opening 440 may be exposed, and portions of the fourth and fifth insulation layers in the third opening 440 may form fourth and fifth insulation patterns 610 and 620, respectively.

A second spacer layer may be formed on the exposed portion of the first spacer layer and the fourth and fifth insulation patterns 610 and 620 in the third opening 440, and may be anisotropically etched to form a second spacer 630 on the exposed portion of the first spacer and the fourth and fifth insulation patterns 610 and 620 to cover a sidewall of the first bit line structure 595.

A dry etching process may be performed using the capping pattern 585 and the second spacer 630 as an etching mask to form a fourth opening 640 exposing an upper surface of the first active structure 305, and upper surfaces of the first isolation pattern 310, and the first gate mask 350 and the first gate insulation pattern 330 may also be exposed by the fourth opening 640.

By the dry etching process, a portion of the first spacer layer on the capping pattern 585 and the second insulation layer 410 may be removed, and thus a first spacer 600 covering a sidewall of the first bit line structure 595 may be formed. Additionally, by the dry etching process, the first and second insulation layers 400 and 410 may also be partially etched so that first and second insulation patterns 405 and 415 may remain under the first bit line structure 595. The first to third insulation patterns 405, 415 and 425 sequentially stacked under the first bit line structure 595 may collectively form a first insulation pattern structure 435.

Referring to FIG. 19, a third spacer layer may be formed on an upper surface of the capping pattern 585, an upper surface and an outer sidewall of the second spacer 630, upper surfaces of the fourth and fifth insulation patterns 610 and 620, and the upper surfaces of the first active structure 305, the first isolation pattern 310, the first gate mask 350 and the first gate insulation pattern 330 exposed by the fourth opening 640, and may be anisotropically etched to form a third spacer 650 on the sidewall of the first bit line structure 595.

The first, second and third spacers 600, 630 and 650 sequentially stacked on the sidewall of the first bit line structure 595 may collectively form a preliminary spacer structure 660.

A sacrificial layer may be formed on the first substrate 300 to fill the fourth opening 640, and may be planarized until the upper surface of the capping pattern 585 is exposed to form a first sacrificial pattern 680 in the fourth opening 640.

In example embodiments, the first sacrificial pattern 680 may extend in the second direction D2, and a plurality of first sacrificial patterns 680 may be spaced apart from each other in the first direction D1 by the first bit line structures 595. The first sacrificial pattern 680 may include an oxide, e.g., silicon oxide.

Referring to FIGS. 20 and 21, a sixth mask including a plurality of fifth openings, each of which may extend in the first direction D1, spaced apart from each other in the second direction D2 may be formed on the capping pattern 585, the first sacrificial pattern 680 and the preliminary spacer structure 660, and the first sacrificial pattern 680 may be etched by an etching process using the sixth mask as an etching mask.

In example embodiments, each of the fifth openings may overlap in the fifth direction D5 an area between the first gate structures 360. By the etching process, a sixth opening exposing upper surfaces of the first active structure 305 and the first isolation pattern 310 may be formed between the first bit line structures 595, and the first sacrificial pattern 680 extending in the second direction D2 between the first bit line structures 595 may be divided into a plurality of parts spaced apart from each other in the second direction D2 by the sixth opening.

In example embodiments, the sixth opening may expose an upper surface of an end portion in the third direction D3 of the first active pattern 304 included in the first active structure 305 and an upper surface of a portion of the first epitaxial pattern 306 on a sidewall of the end portion in the third direction D3 of the first active pattern 304. Thus, an area of the sixth opening exposing the upper surface of the first active structure 305 may be increased when compared to a case in which the first active structure 305 does not include the first epitaxial pattern 306 but includes only the first active pattern 304.

After removing the sixth mask, a lower contact plug layer may be formed to fill the sixth opening, and may be planarized until upper surfaces of the capping pattern 585, the first sacrificial pattern 680 and the preliminary spacer structure 660 are exposed. Thus, the lower contact plug layer may be divided into a plurality of lower contact plugs 675 spaced apart from each other in the second direction D2 by the first sacrificial pattern 680 between the first bit line structures 595.

As the sixth opening exposes the increased area of the upper surface of the first active structure 305, the lower contact plug 675 in the sixth opening may contact the upper surface of the first active structure 305 at an increased area. That is, the lower contact plug 675 may contact not only the upper surface of the end portion in the third direction D3 of the first active pattern 304 but also the upper surface of the first epitaxial pattern 306 on the sidewall of the end portion in the third direction D3 of the first active pattern 304, so as to contact the first active structure 305 including the first active pattern 304 and the first epitaxial pattern 306 at the increased area.

The first sacrificial pattern 680 may be removed to form a seventh opening, and a first fence pattern 685 may be formed in the seventh opening. In example embodiments, the first fence pattern 685 may overlap the first gate structure 360 in the fifth direction D5.

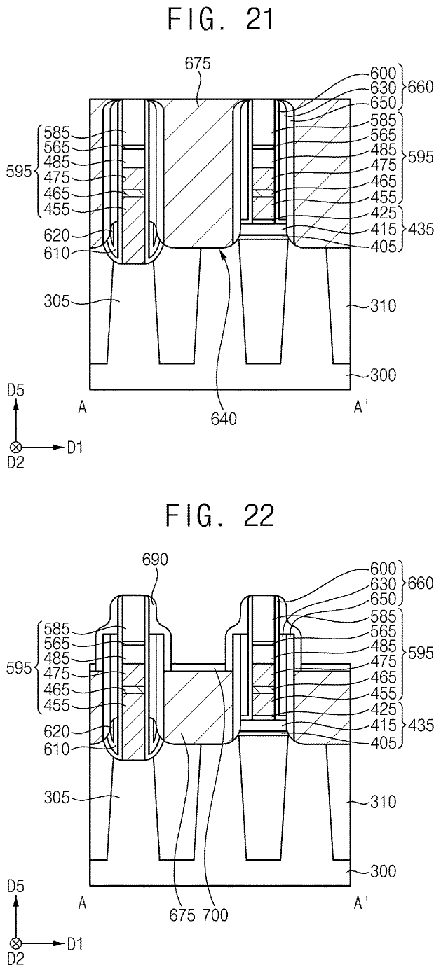

Referring to FIG. 22, an upper portion of the lower contact plug 675 may be removed to expose an upper portion of the preliminary spacer structure 660 on the sidewall of the first bit line structure 595, and upper portions of the second and third spacers 630 and 650 of the preliminary spacer structure 660 may be removed.

An upper portion of the lower contact plug 675 may be further removed. Thus, an upper surface of the lower contact plug 675 may be lower than upper surfaces of the second and third spacers 630 and 650.

A fourth spacer layer may be formed on the first bit line structure 595, the preliminary spacer structure 660, the first fence pattern 685 and the lower contact plug 675, and may be anisotropically etched to form a fourth spacer 690 covering an upper portion of the preliminary spacer structure 660 on each of opposite sidewalls in the first direction D1 of the first bit line structure 595, and thus an upper surface of the lower contact plug 675 may be exposed.

A metal silicide pattern 700 may be formed on the upper surface of the lower contact plug 675. In example embodiments, the metal silicide pattern 700 may be formed by forming a first metal layer on the capping patterns 585, the first fence pattern 685, the fourth spacer 690 and the lower contact plug 675, performing a heat treatment process, and removing an unreacted portion of the first metal layer.

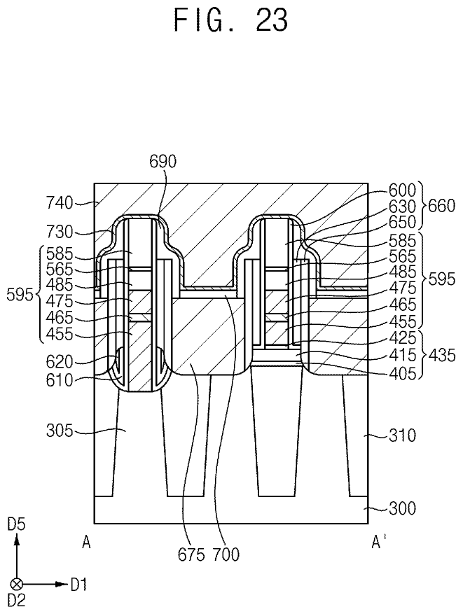

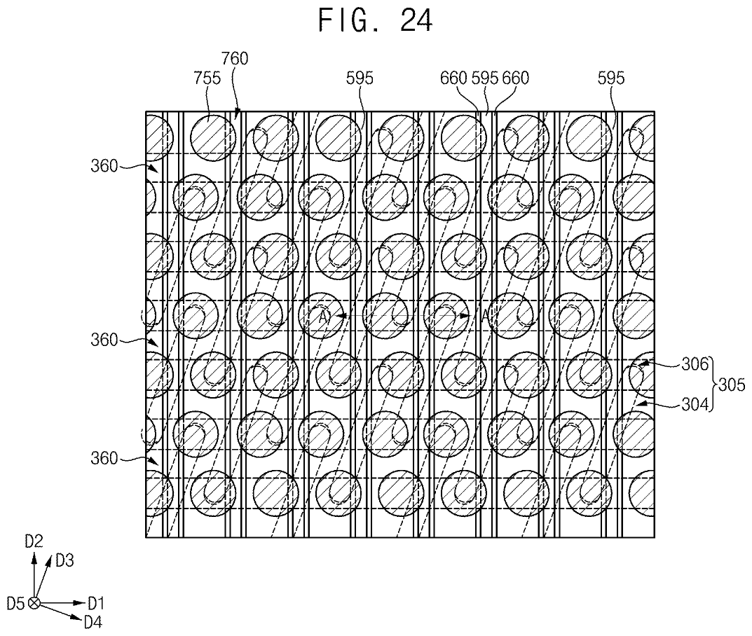

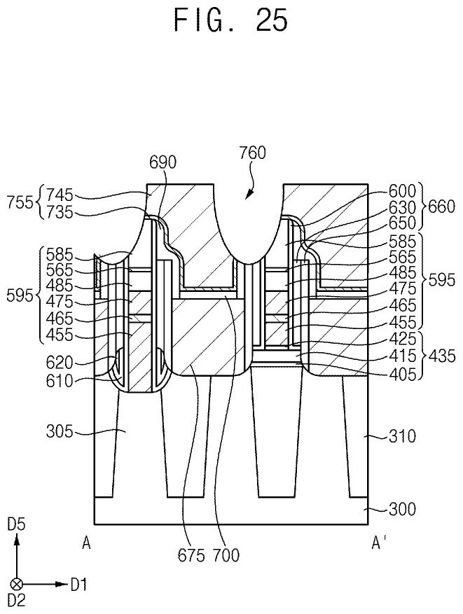

Referring to FIG. 23, a second barrier layer 730 may be formed on the capping pattern 585, the first fence pattern 685, the fourth spacer 690, the metal silicide pattern 700 and the lower contact plug 675, and a second metal layer 740 may be formed on the second barrier layer 730 to fill a space between the first bit line structures 595.

A planarization process may be further performed on an upper portion of the second metal layer 740. The planarization process may include a CMP process and/or an etch back process.

Referring to FIGS. 24 and 25, the second metal layer 740 and the second barrier layer 730 may be patterned to form an upper contact plug 755, and an eighth opening 760 may be formed between the upper contact plugs 755.

The eighth opening 760 may be formed by partially removing the capping pattern 585, the first fence pattern 685, the preliminary spacer structure 660 and the fourth spacer 690 as well as the second metal layer 740 and the second barrier layer 730.

The upper contact plug 755 may include a second metal pattern 745 and a second barrier pattern 735 covering a lower surface of the second metal pattern 745. In example embodiments, the upper contact plug 755 may have a shape of, e.g., a circle, an ellipse, a polygon, a polygon with rounded corners, etc., and may be arranged in a honeycomb pattern in the first and second directions D1 and D2.

The lower contact plug 675, the metal silicide pattern 700 and the upper contact plug 755 sequentially stacked may collectively form a first contact plug structure.

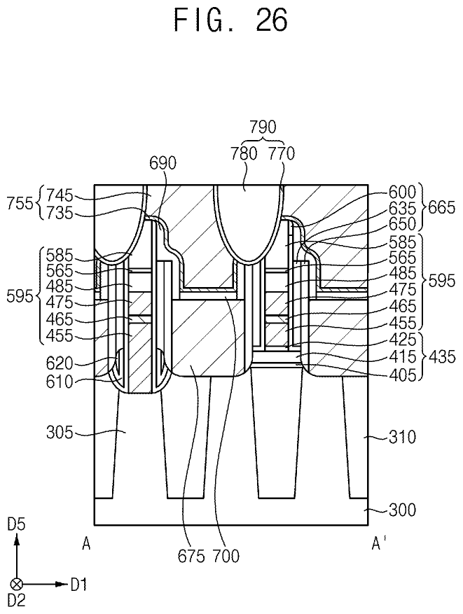

Referring to FIG. 26, the second spacer 630 included in the preliminary spacer structure 660 exposed by the eighth opening 760 may be removed to form an air gap, a sixth insulation pattern 770 may be formed on a bottom and a sidewall of the eighth opening 760, and a seventh insulation pattern 780 may be formed to fill a remaining portion of the eighth opening 760.

The sixth and seventh insulation patterns 770 and 780 may collectively form a second insulation pattern structure 790.

A top of the air gap may be covered by the sixth insulation pattern 770, and thus an air spacer 635 may be formed. The first spacer 600, the air spacer 635 and the third spacer 650 may collectively form a spacer structure 665.

Referring to FIGS. 1 to 3 again, a second etch stop layer 800 and a first mold layer may be sequentially stacked on the upper contact plug 755 and the second insulation pattern structure 790, the first mold layer and the second etch stop layer 800 may be partially removed to form a ninth opening exposing an upper surface of the upper contact plug 755, and a first lower electrode 810 may be formed in the ninth opening.

The first mold layer may be removed, a first dielectric layer 820 may be formed on a surface of the first lower electrode 810, and a first upper electrode 830 may be formed on the first dielectric layer 820 to form a first capacitor 840.

Upper wirings may be further formed to complete the fabrication of the semiconductor device.

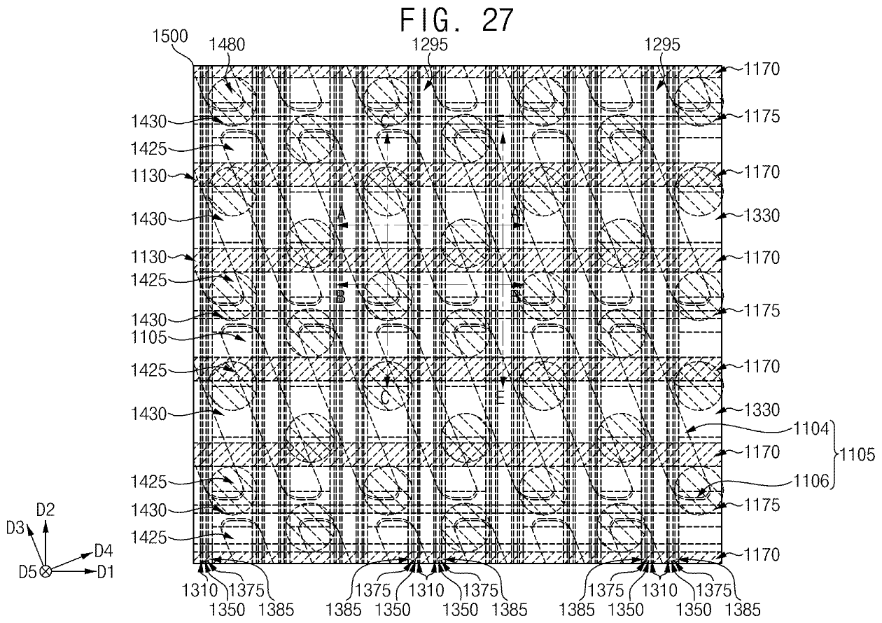

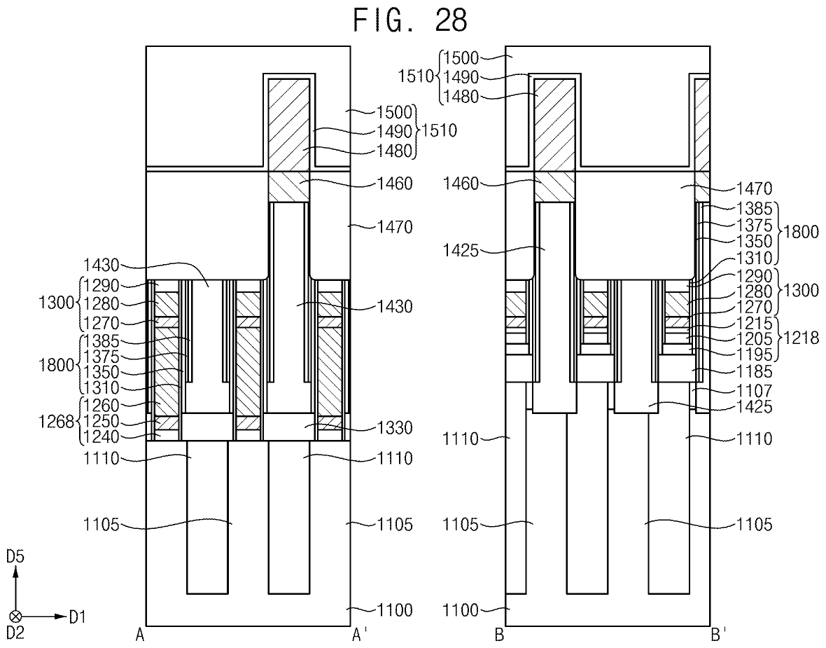

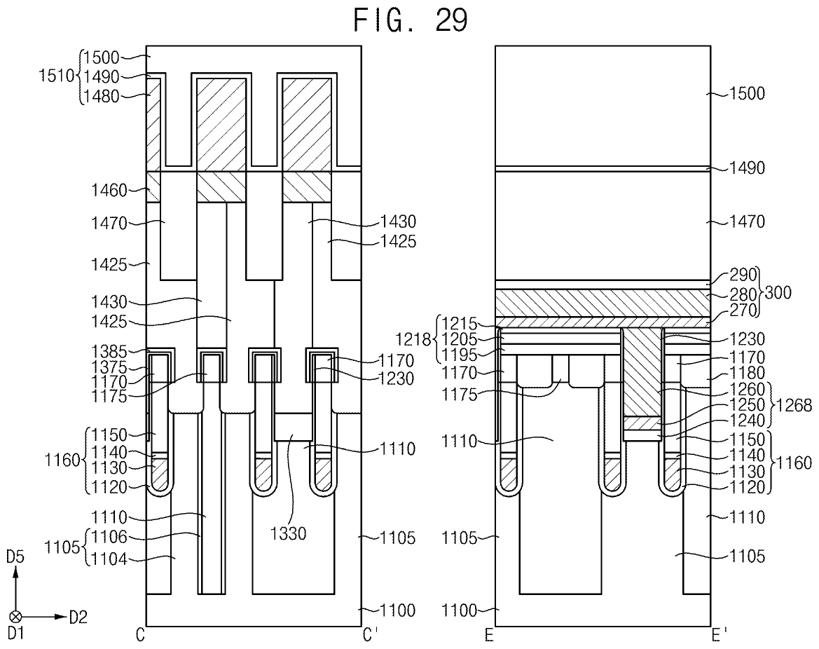

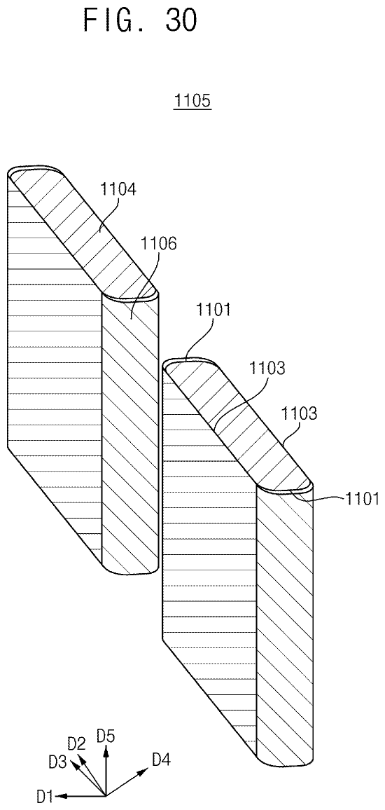

FIGS. 27 to 29 are a plan view and cross-sectional views illustrating a semiconductor device in accordance with example embodiments. Specifically, FIG. 27 is the plan view, FIG. 28 includes cross-sectional views taken along lines A-A′ and B-B′, respectively, of FIG. 27, and FIG. 29 includes cross-sectional views taken along lines C-C′ and E-E′, respectively, of FIG. 27. FIG. 30 is a perspective view illustrating a second active structure included in the semiconductor device.

This semiconductor device may include elements that are substantially the same as or similar to those of the semiconductor device of FIGS. 1 to 3, and thus repeated explanations thereof are omitted herein.

Referring to FIGS. 27 to 30, the semiconductor device may include a second active structure 1105, a second gate structure 1160, a second bit line structure 1300, a second spacer structure 1800, a buffer structure 1218, a filling pattern 1330, a second contact structure 1268, a second fence pattern 1430, a third contact structure 1425, a landing pad 1460 and a second capacitor 1510 on a second substrate 1100.

The semiconductor device may further include a second isolation pattern 1110, a second mold layer 1170, a third mold layer 1175, a fourth mold 1185, a fifth spacer 1230 and an eighth insulation pattern 1470.

The second active structure 1105 may include a second active pattern 1104 and a second epitaxial pattern 1106. In example embodiments, the second active structure 1105 may extend in the third direction D3 to a given length, and a plurality of second active structures 1105 may be spaced apart from each other in the first direction D1 to form a second active structure row. Additionally, a plurality of second active structure rows may be disposed in the second direction D2 to form a second active structure array.

In example embodiments, the second active structures 1105 included in each of the second active structure rows may be aligned with each other in the first direction D1. That is, corresponding end portions of the second active structures 1105 included in each of the second active structure rows may be disposed in the same line extending in the first direction D1.

The second active pattern 1104 included in each of the second active structures 1105 may extend in the third direction D3 to a given length. That is, an extension length in the third direction D3 of the second active pattern 1104 may be greater than a width in the fourth direction D4 of the second active pattern 1104. In example embodiments, each of opposite end portions in the third direction D3 of the second active pattern 1104 may have a curved shape, e.g., a rounded shape in a plan view.

In example embodiments, extension lengths in the third direction D3 of the second active patterns 1104 may be substantially the same as each other, and widths in the fourth direction D4 of the second active patterns 1104 may be substantially the same as each other.

The second epitaxial pattern 1106 may be disposed on a sidewall of each of opposite end portions in the third direction D3 of each of the second active patterns 1104. In example embodiments, each of the second active patterns 1104 may include first sidewalls 1101 opposite to each other in the third direction D3 and second sidewalls 1103 opposite to each other in the fourth direction D4, and the second epitaxial pattern 1106 may be disposed on each of the first sidewalls 1101 of the second active pattern 1104. Each of the first sidewalls 1101 of the second active pattern 1104 may have a shape of a line extending in the third direction D3 in a plan view, and each of the second sidewalls 1103 of the second active pattern 1104 may have a shape of a curve, e.g., a rounded shape in a plan view.

In example embodiments, the second epitaxial patterns 1106 on the first sidewalls 1101, respectively, of each of the second active patterns 1104 may overlap each other neither in the first direction D1 nor in the fourth direction D4.

In an example embodiment, the second epitaxial pattern 1106 may have a constant thickness on the sidewall of each of opposite end portions in the third direction D3 of the second active pattern 1104, however, the inventive concept is not limited thereto. Each of opposite end portions in the third direction D3 of the second active structure 1105 including the second active pattern 1104 and the second epitaxial pattern 1106 may have a curved shape, e.g., a rounded shape in a plan view.

In example embodiments, an uppermost surface of the second epitaxial pattern 1106 may be substantially coplanar with an upper surface of the second active pattern 1104, and a lowermost surface of the second epitaxial pattern 1106 may be substantially coplanar with a lower surface of the second active pattern 1104.

In example embodiments, the second epitaxial pattern 1106 may include a material substantially the same as that of the second active pattern 1104, e.g., a single crystalline semiconductor material. In an example embodiment, a crystalline orientation of the second epitaxial pattern 1106 may be different from that of the second active pattern 1104, and thus the second epitaxial pattern 1106 and the second active pattern 1104 may be distinguished from each other. Alternatively, the crystalline orientation of the second epitaxial pattern 1106 may be substantially the same as that of the second active pattern 1104, and thus the second epitaxial pattern 1106 and the second active pattern 1104 may not be distinguished from each other.

In an example embodiment, the second epitaxial patterns 1106 may have the same crystalline orientation. Alternatively, the second epitaxial patterns 1106 may have different crystalline orientations from each other.

If some ones of the second epitaxial patterns 1106 disposed on sidewalls of first ones of the second active patterns 1104 have the same crystalline orientation as that of the first ones of the second active patterns 1104 so as to be merged thereto, and other ones of the second epitaxial patterns 1106 disposed on sidewalls of second ones of the second active patterns 1104 have different crystalline orientations from that of the second ones of the second active patterns 1104 so as to be distinguished therefrom, extension lengths in the third direction D3 of the first ones of the second active patterns 1104 including the second epitaxial patterns 1106 merged thereto may be greater than extension lengths in the third direction D3 of the second ones of the second active patterns 1104 not including the second epitaxial patterns 1106.

An impurity region structure 1107 may be disposed at an upper portion of each of end portions of the second active structure 1105 in the third direction D3. The impurity region structure 1107 may include a first impurity region 1107a in the second active pattern 1104, and a second impurity region 1107b in the second epitaxial pattern 1106. The impurity region structure 1107 may include, for example, n-type impurities or p-type impurities.

In example embodiments, an upper surface of a central portion in the third direction D3 of the second active structure 1105 and an upper surface of a portion of the second isolation pattern 1110 adjacent thereto in the first direction D1 may be lower than an upper surface of the end portion in the third direction D3 of the second active structure 1105 and an upper surface of a portion of the second isolation pattern 1110 adjacent thereto in the first direction D1.

The second gate structure 1160 may extend in the first direction D1 through upper portions of the second active structure 1105 and the second isolation pattern 1110, and a plurality of second gate structures 1160 may be spaced apart from each other in the second direction D2. The second gate structure 1160 may include a third conductive pattern 1130, a fourth conductive pattern 1140 and a second gate mask 1150 sequentially stacked in the fifth direction D5, and may further include a second gate insulation pattern 1120, which may cover sidewalls of the third conductive pattern 1130, the fourth conductive pattern 1140 and the second gate mask 1150 and a lower surface of the third conductive pattern 1130. The third and fourth conductive patterns 1130 and 1140 may collectively form a second gate electrode.

The third conductive pattern 1130 may include, e.g., a metal, a metal nitride, a metal silicide, etc., and the fourth conductive pattern 1140 may include, e.g., doped polysilicon.

In an embodiment, two second gate structures 1160 spaced apart from each other in the second direction D2 may extend through an upper portion of a single second active structure 1105.

The second contact structure 1268 may be disposed on the central portion of the second active structure 1105, and may include a second pad 1240, an ohmic contact pattern 1250 and a fourth metal pattern 1260 sequentially stacked in the fifth direction D5. In example embodiments, a plurality of second contact structures 1268 may be spaced apart from each other in each of the first and second directions D1 and D2. The second pad 1240 may include, e.g., polysilicon doped with impurities, the ohmic contact pattern 1250 may include a metal silicide, e.g., cobalt silicide, nickel silicide, titanium silicide, etc., and the fourth metal pattern 1260 may include a metal, e.g., tungsten, niobium, copper, aluminum, etc.

The second mold layer 1170, the third mold layer 1175 and the fourth mold 1185 may be disposed on the second active structure 1105 and the second isolation pattern 1110. Each of the second and third mold layers 1170 and 1175 may extend in the first direction D1. A plurality of second mold layers 1170 may be spaced apart from each other in the second direction D2, and a plurality of third mold layers 1175 may be spaced apart from each other in the second direction D2.

A plurality of fourth molds 1185 may be spaced apart from each other in each of the first and second directions D1 and D2, and the fourth molds 1185 may be disposed under the second bit line structure 1300.

In example embodiments, upper surfaces of the second and third mold layers 1170 and 1175 and an upper surface of the fourth mold 1185 may be substantially coplanar with each other. A lowermost surface of the fourth mold 1185 may be lower than lower surfaces of the second and third mold layers 1170 and 1175.

The second mold layer 1170 and the third mold layer 1175 may include an insulating nitride, e.g., silicon nitride, and the fourth mold 1185 may include an oxide, e.g., silicon oxide.

The buffer structure 1218 may be disposed between the second bit line structure 1300 and the second and third mold layers 1170 and 1175 and the fourth mold 1185, and may include first to third buffers 1195, 1205 and 1215 sequentially stacked in the fifth direction D5. A plurality of buffer structures 218 may be spaced apart from each other in each of the first and second directions D1 and D2. The first buffer 1195 may include an oxide, e.g., silicon oxide, the second buffer 1205 may include a high-k material, and the third buffer 1215 may include a nitride, e.g., silicon nitride.

The second bit line structure 1300 may extend in the second direction D2, and a plurality of second bit line structures 1300 may be spaced apart from each other in the first direction D1. The second bit line structure 1300 may overlap the central portion of the second active structure 1105 in the fifth direction D5, and the second contact structure 1268 may be disposed between the second bit line structure 1300 and the second active structure 1105. The second bit line structure 1300 may contact an upper surface of the buffer structure 1218.

The second bit line structure 1300 may include a third barrier pattern 1270, a fifth metal pattern 1280 and a seventh mask 1290 sequentially stacked in the fifth direction D5. The third barrier pattern 1270 may include a metal nitride, e.g., titanium nitride or a metal silicon nitride, e.g., titanium silicon nitride, the fifth metal pattern 1280 may include a metal, e.g., tungsten, and the seventh mask 1290 may include an insulating nitride, e.g., silicon nitride.

The filling pattern 1330 may be disposed on a portion of the second isolation pattern 1110 adjacent to the central portion of the second active structure 1105 in the first direction D1, and may be disposed between the second contact structures 1268 neighboring in the first direction D1. A plurality of filling patterns 1330 may be spaced apart from each other in the second direction D2 between neighboring ones of the second bit line structures 1300 in the first direction D1. Additionally, a plurality of filling patterns 1330 may be spaced apart from each other in the first direction D1 between neighboring ones of the second gate structures 1160 in the second direction D2.

In example embodiments, a lower surface of the filling pattern 1330 may be substantially coplanar with a lower surface of the central portion of the second active structure 1105 and a lower surface of the second contact structure 1268, and may be higher than an upper surface of the fourth conductive pattern 1140 of the second gate structure 1160. Additionally, an upper surface of the filling pattern 1330 may be lower than the upper surface of the end portion of the second active structure 1105.

The filling pattern 1330 may include an insulating nitride, e.g., silicon nitride or silicon oxycarbonitride.

The fifth spacer 1230 may be disposed on a sidewall of the second mold layer 1170 and a sidewall of the buffer structure 1218. In some embodiments, the fifth spacer 1230 may not be formed. The fifth spacer 1230 may include an insulating nitride, e.g., silicon nitride.

The second spacer structure 1800 may include a sixth spacer 1310, a seventh spacer 1350, a third etch stop pattern 1375 and an eighth spacer 1385 sequentially stacked in the first direction D1 on a sidewall in the first direction D1 of the second bit line structure 1300.

In example embodiments, each of the sixth and seventh spacers 1310 and 1350 may extend in the second direction D2.

In example embodiments, the sixth spacer 1310 may contact each of opposite sidewalls in the first direction D1 of the second contact structure 1268 and each of opposite sidewalls in the first direction D1 of the second bit line structure 1300. Additionally, the sixth spacer 1310 may also contact each of opposite sidewalls in the first direction D1 of each of the second and third buffers 1205 and 1215 and an upper surface of each of end portions in the first direction D1 of the first buffer 1195.

Thus, a lowermost surface of the sixth spacer 1310 may be substantially coplanar with the upper surface of the central portion of the second active structure 1105, the upper surface of the portion of the second isolation pattern 1110 adjacent thereto in the first direction D1, and the lower surface of the filling pattern 1330.

In example embodiments, the seventh spacer 1350 may contact each of opposite sidewalls in the first direction D1 of the sixth spacer 1310 and each of opposite sidewalls in the first direction D1 of the first buffer 1195. Additionally, the seventh spacer 1350 may also contact an upper surface of each of opposite end portions in the first direction D1 of the fourth mold 1185 and an upper surface of each of opposite end portions in the first direction D1 of the filling pattern 1330.

Thus, a lowermost surface of the seventh spacer 1350 may be substantially coplanar with the upper surface of the filling pattern 1330, and may be higher than the lower surface of the sixth spacer 1310.

The third etch stop pattern 1375 and the eighth spacer 1385 may be sequentially stacked on each of opposite sidewalls in the first direction D1 of the seventh spacer 1350, each of opposite sidewalls in the first direction D1 of the fourth mold 1185, each of opposite sidewalls in the second direction D2 and upper surfaces of the second and third mold layers 1170 and 1175, and an outer sidewall in the second direction D2 of the fifth spacer 1230.

In example embodiments, a lower surface of the third etch stop pattern 1375 and a lower surface of the eighth spacer 1385 may be substantially coplanar with the upper surface of the end portion of the second active structure 1105, and thus may be higher than the lowermost surface of the seventh spacer 1350.

Each of the sixth spacer 1310 and the eighth spacer 1385 may include an insulating nitride, e.g., silicon nitride, and each of the seventh spacer 1350 and the third etch stop pattern 1375 may include an oxide, e.g., silicon oxide.

The third contact structure 1425 may be disposed on each of opposite end portions of the second active structure 1105, and may contact the impurity region structure 1107. A plurality of third contact structures 1425 may be spaced apart from each other in each of the first and second directions D1 and D2.

In example embodiments, the third contact structure 1425 may include a lower portion having a first width in the first direction D1 and an upper portion on the lower portion and having a second width in the first direction D1 less than the first width. The lower portion of the third contact structure 1425 may contact the second active structure 1105 and a portion of the second isolation pattern 1110 adjacent thereto.

The second active structure 1105 may include not only the second active pattern 1104 but also the second epitaxial pattern 1106 on each of the end portions in the third direction D3 of the second active pattern 1104. Thus, the second active structure 1105 may have an increased area, and a contact area between the third contact plug structure 1425 and the second active structure 1105 may increase to reduce a contact resistance therebetween.

A sidewall of the upper portion of the third contact structure 1425 may be covered by the eighth spacer 1385. In example embodiments, the lower surface of the third etch stop pattern 1375 and the lower surface of the eighth spacer 1385 may contact an upper surface of an edge of the upper portion of the third contact structure 1425.

The third contact structure 1425 may include, e.g., doped polysilicon.

The second fence pattern 1430 may be disposed on the filling pattern 1330, and may also be disposed on a portion of the eighth spacer 1385 on the first and second mold layers 1170 and 1175. In example embodiments, a plurality of second fence patterns 1430 may be spaced apart from each other in each of the first and second directions D1 and D2.

The second fence pattern 1430 may include a lower portion having a first width in the first direction D1 and an upper portion on the lower portion and having a second width in the first direction D1 less than the first width. The lower portion and the upper portion of the second fence pattern 1430 may be substantially coplanar with the lower portion and the upper portion, respectively, of the third contact structure 1425.

A lower surface of the lower portion of the second fence pattern 1430 may contact the upper surface of the filling pattern 1330, and a sidewall in the first direction D1 of the lower portion of the second fence pattern 1430 may contact an outer sidewall of the seventh spacer 1350. Additionally, a sidewall in the first direction D1 of the upper portion of the second fence pattern 1430 may contact the eighth spacer 1385, and a sidewall in the second direction D2 of the upper portion of the second fence pattern 1430 may contact the third contact structure 1425.

The second fence pattern 1430 may include an insulating nitride, e.g., silicon nitride, silicon oxycarbonitride, etc.

The landing pad 1460 may contact the upper surface of the third contact structure 1425, and a plurality of landing pads 1460 may be spaced apart from each other in each of the first and second directions D1 and D2. In example embodiments, the landing pad 1460 may have a shape of, e.g., a circle, an ellipse, a polygon, a polygon with rounded corners, etc., in a plan view, and the landing pads 1460 may be arranged in a honeycomb pattern in a plan view. The landing pad 1460 may include, e.g., a metal, a metal nitride, etc.

The eighth insulation pattern 1470 may cover sidewalls of the landing pads 1460, and may partially extend through upper portions of the second bit line structure 1300, the third contact structure 1425 and the second fence pattern 1430. The eighth insulation pattern 1470 may include an insulating nitride, e.g., silicon nitride.

The second capacitor 1510 may include a second lower electrode 1480, a second dielectric layer 1490 and a second upper electrode 1500 sequentially stacked, and the second lower electrode 1480 may contact an upper surface of the landing pad 1460.

In the semiconductor device in accordance with example embodiments, the second bit line structure 1300 may be electrically connected to the central portion of the second active structure 1105 through the second contact plug structure 1268, and the second capacitor 1510 may be electrically connected to the end portion of the second active structure 1105 through the landing pad 1460 and the third contact plug structure 1425.

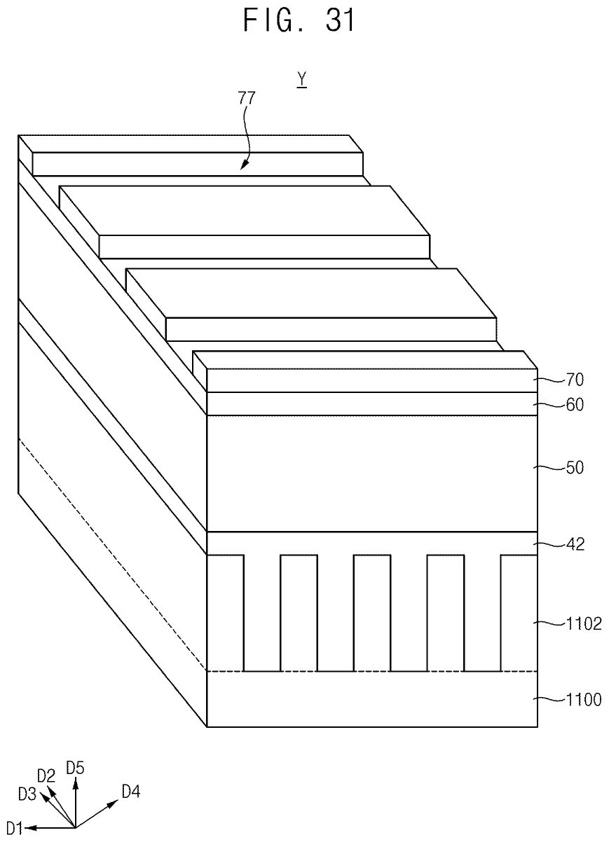

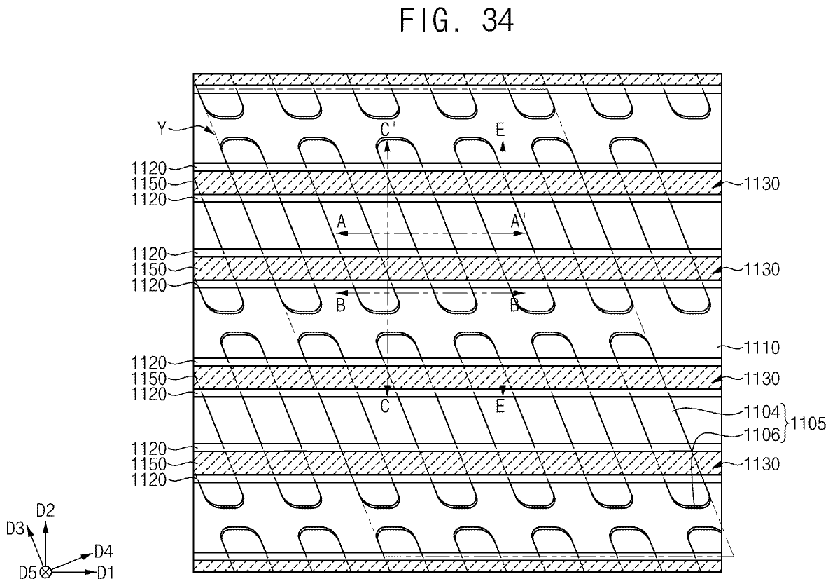

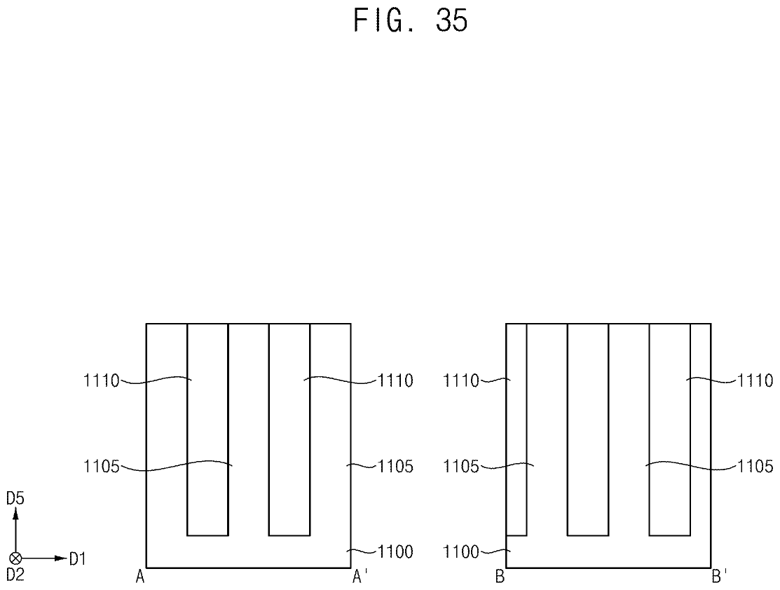

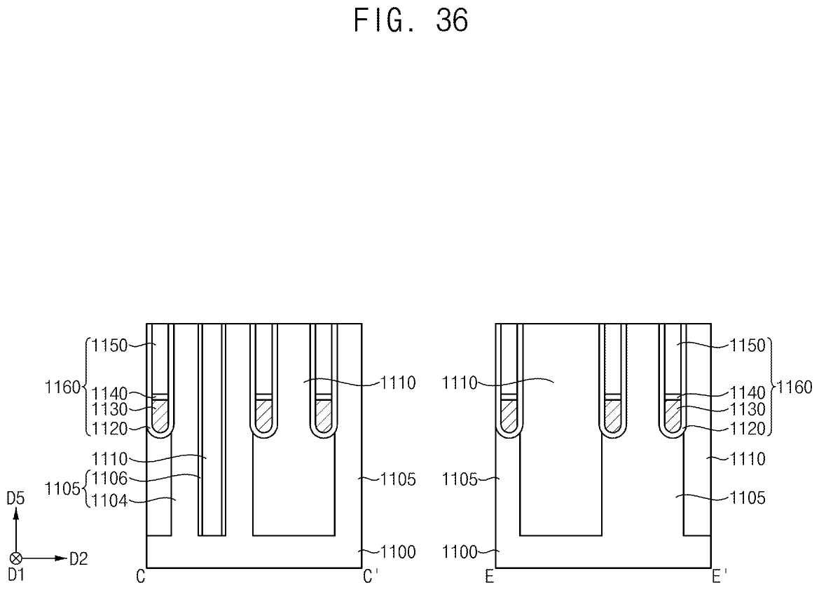

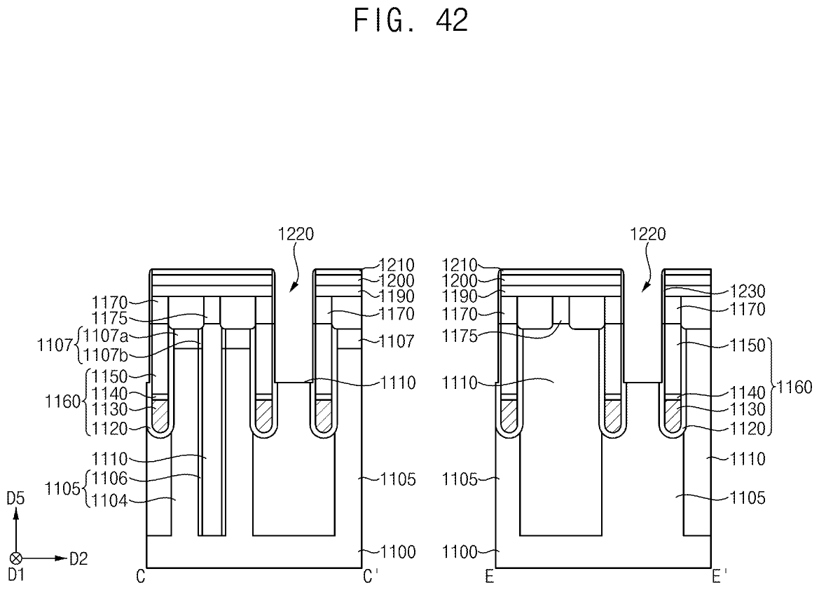

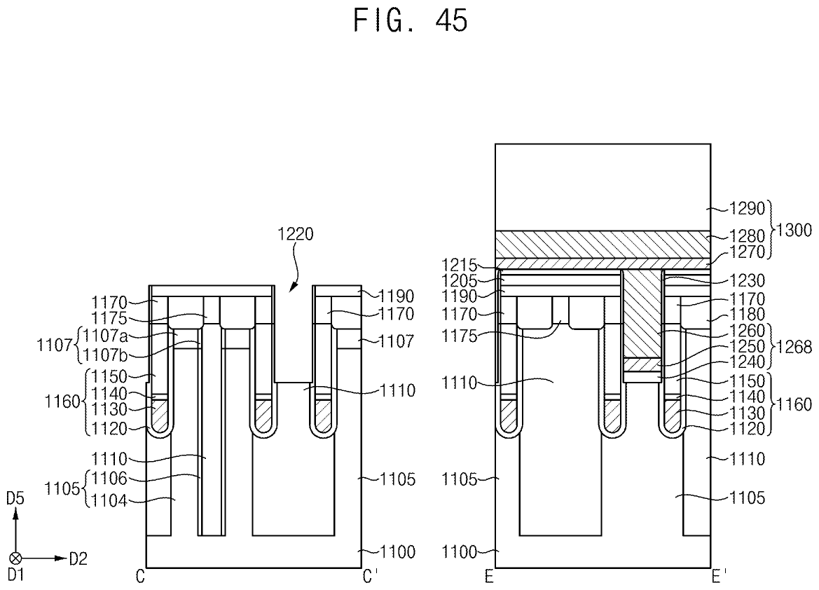

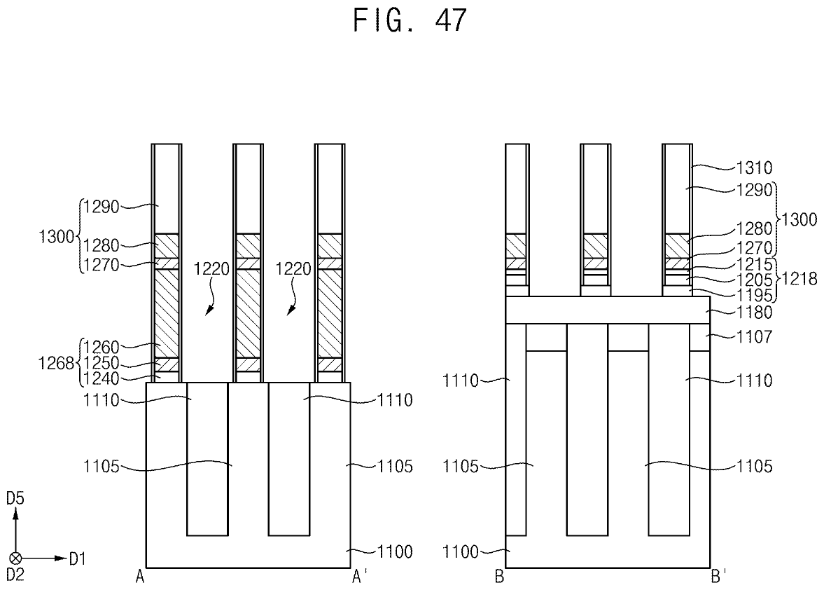

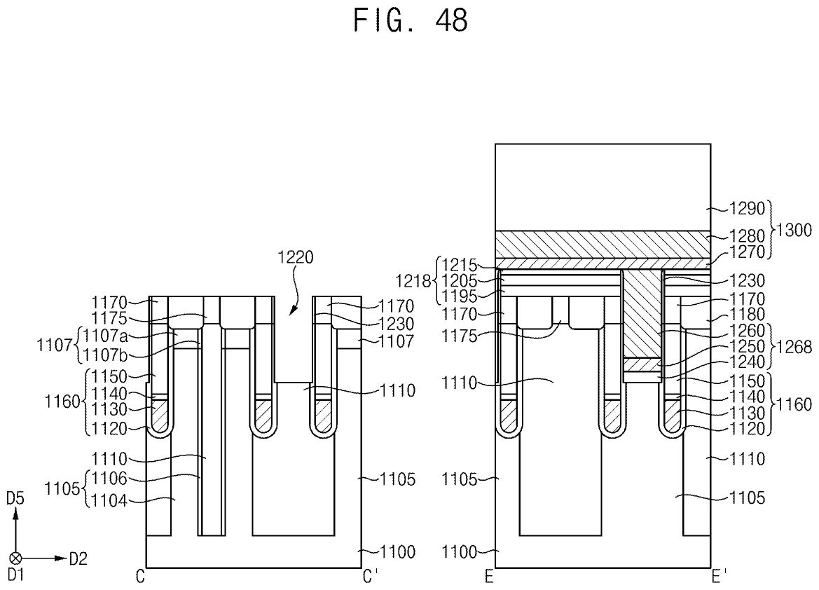

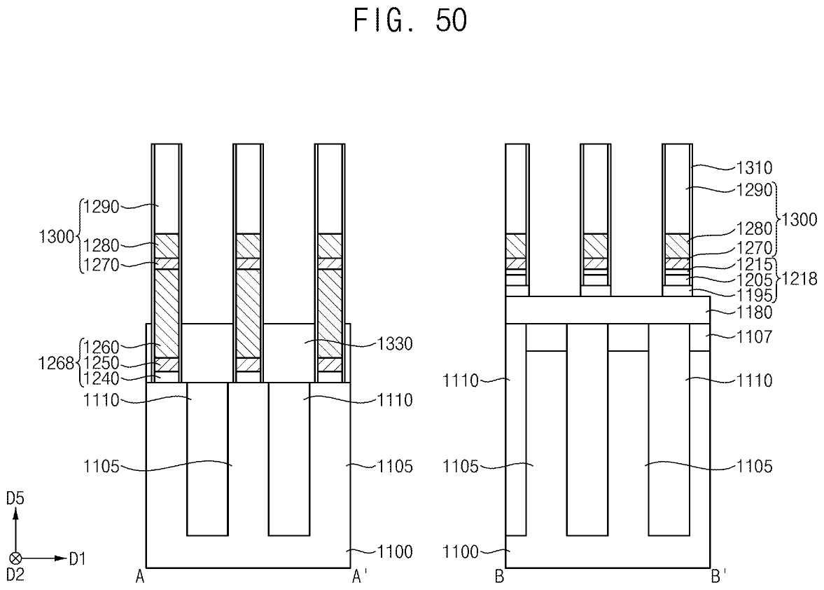

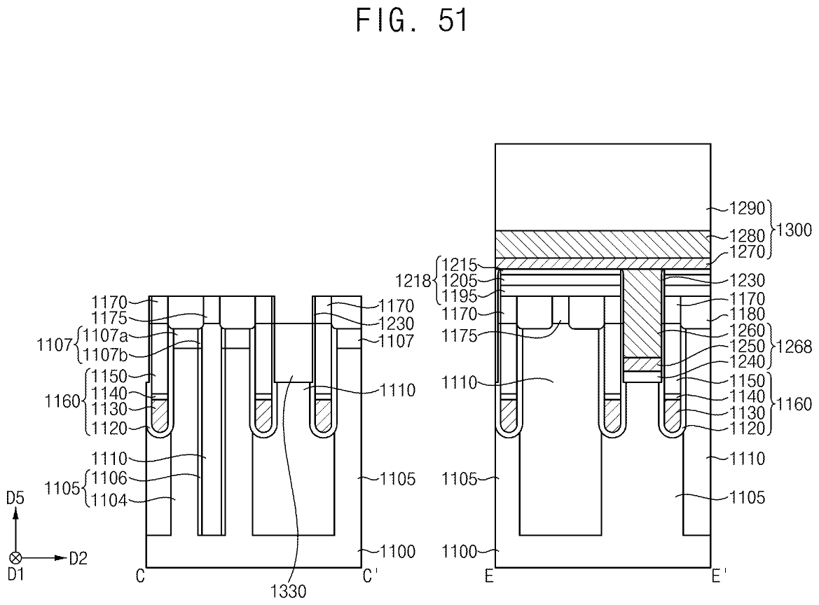

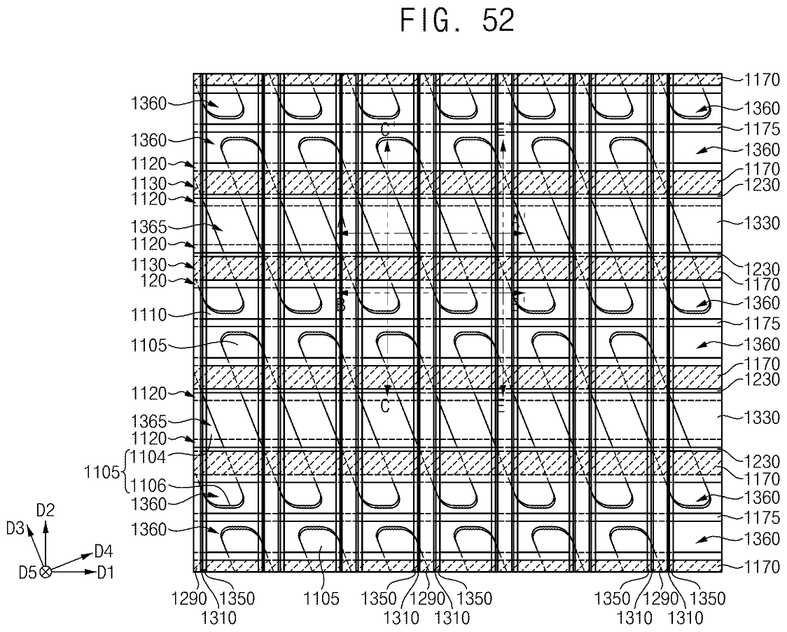

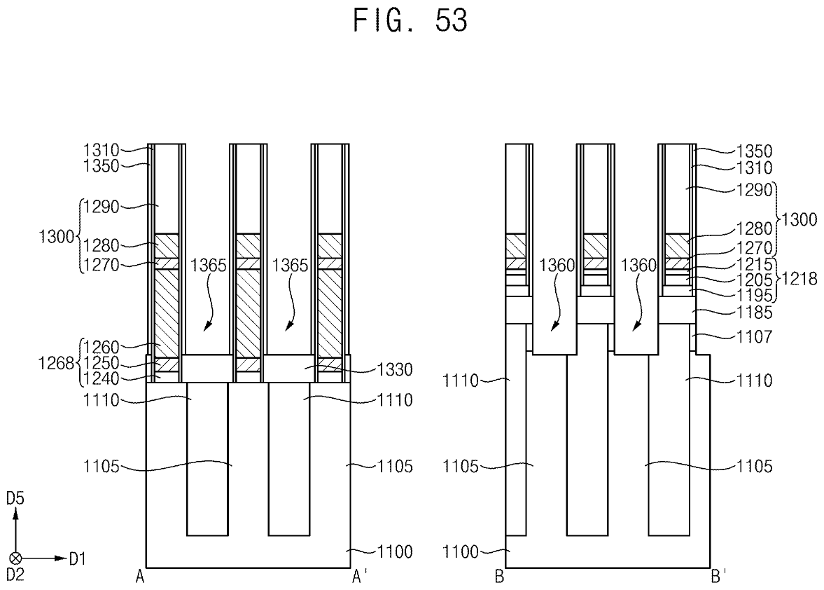

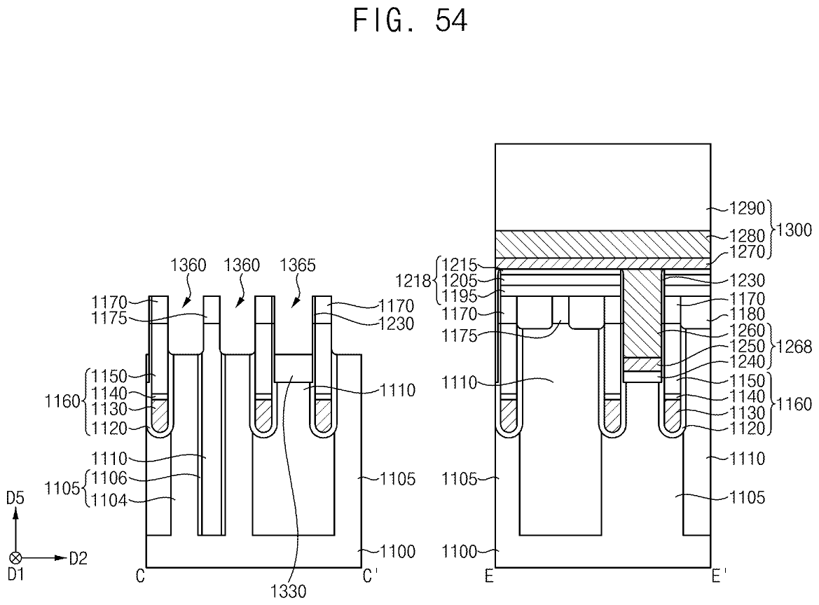

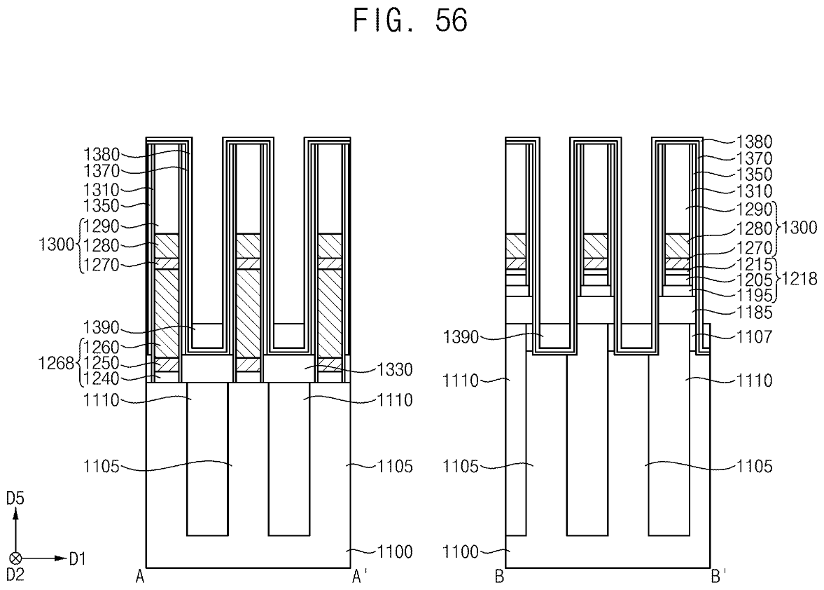

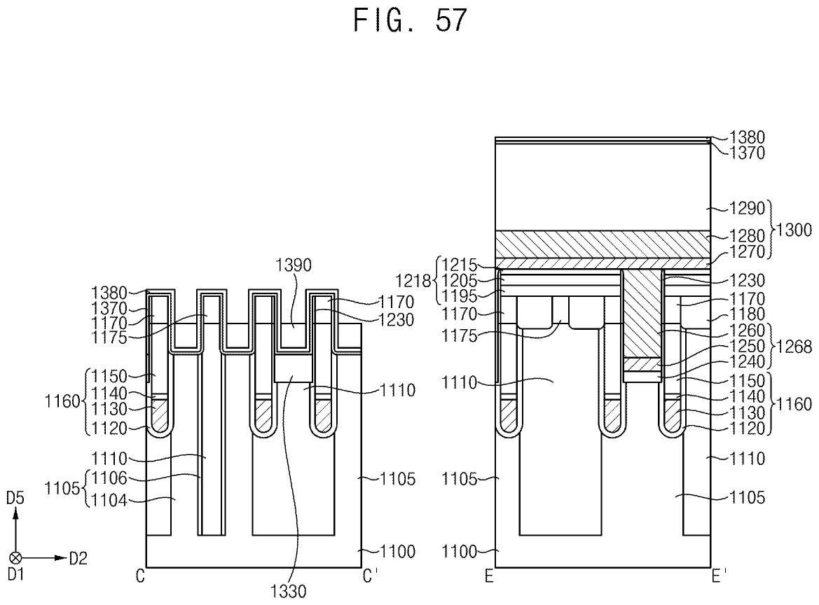

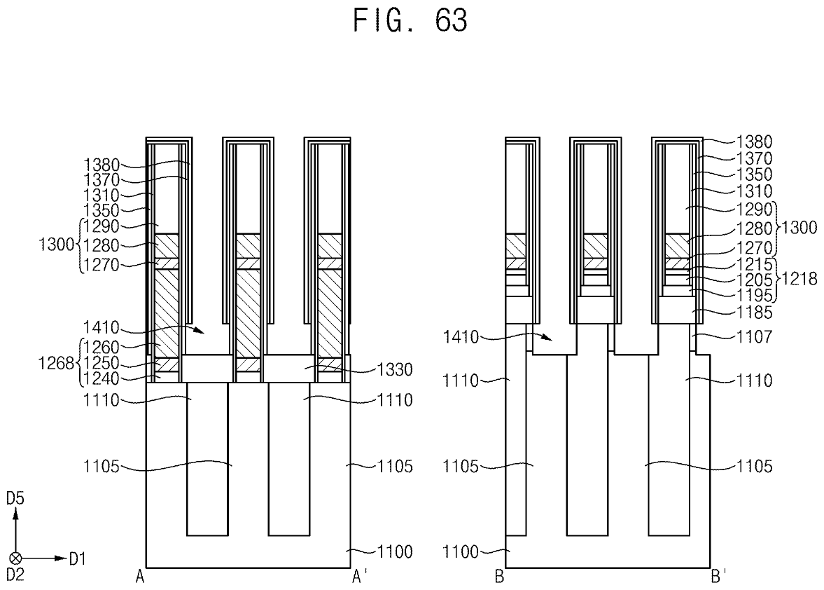

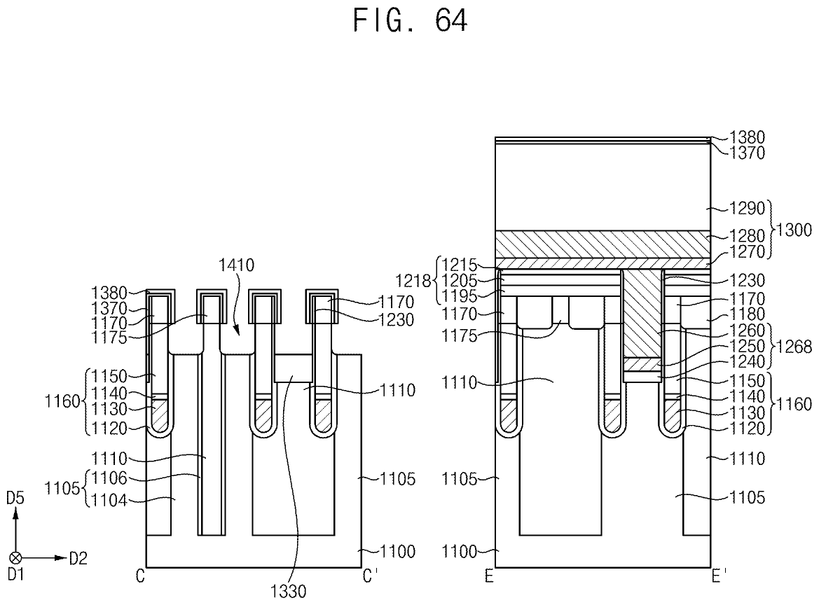

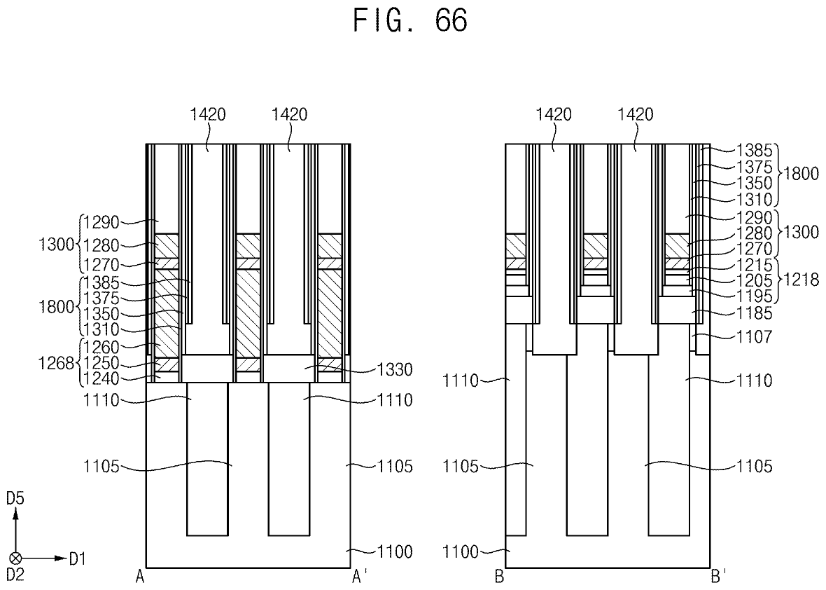

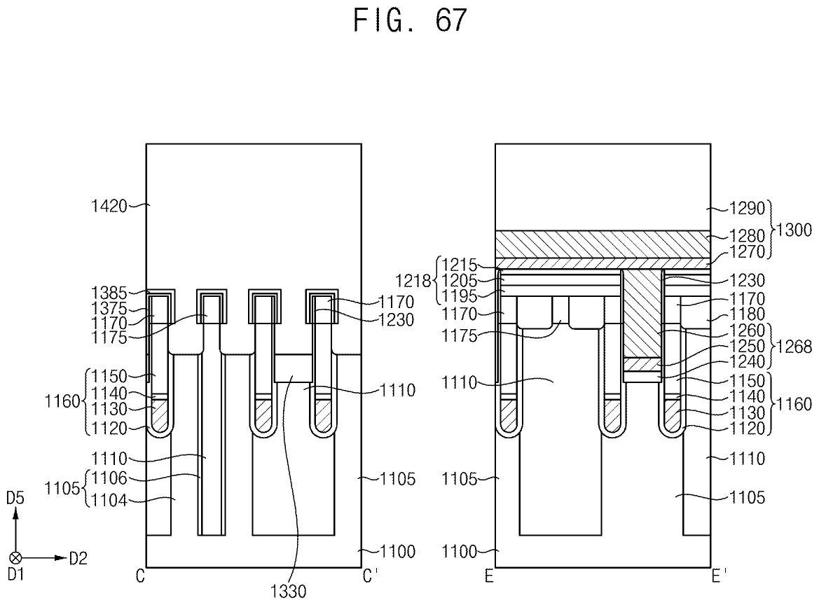

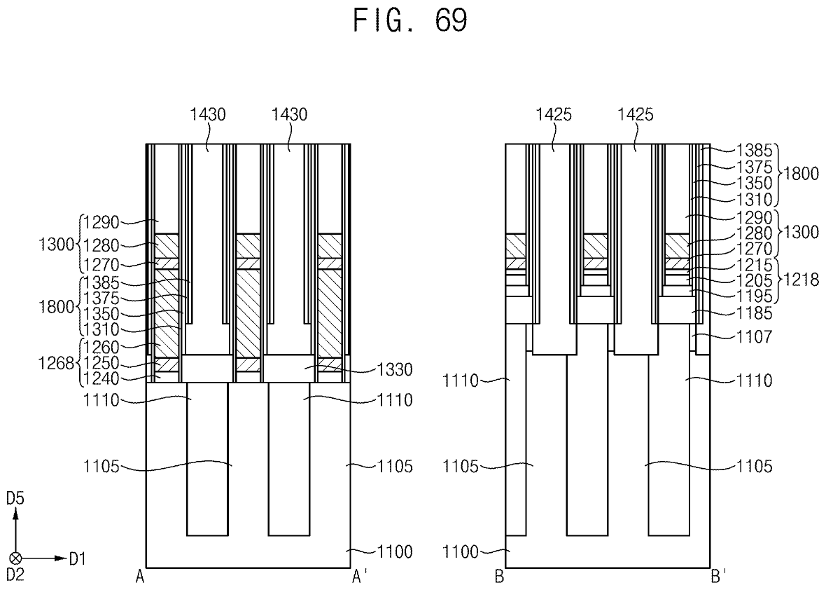

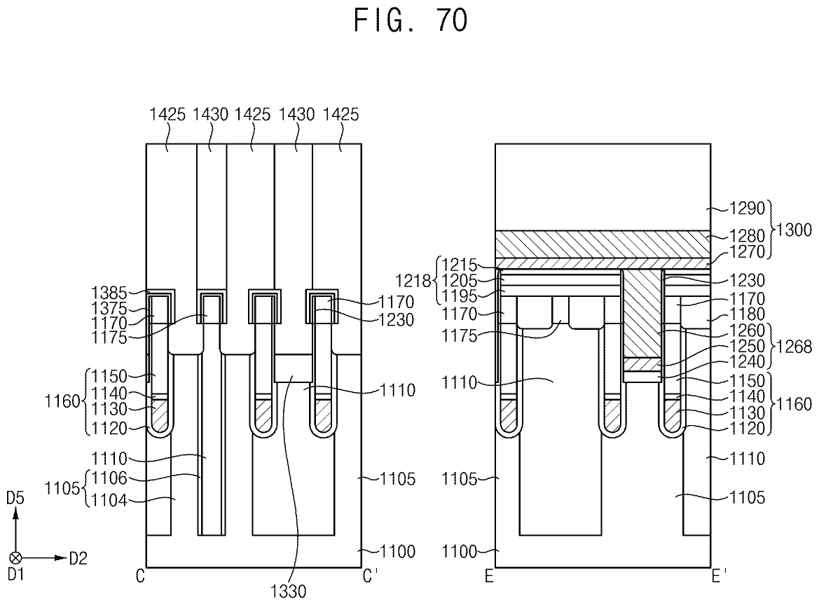

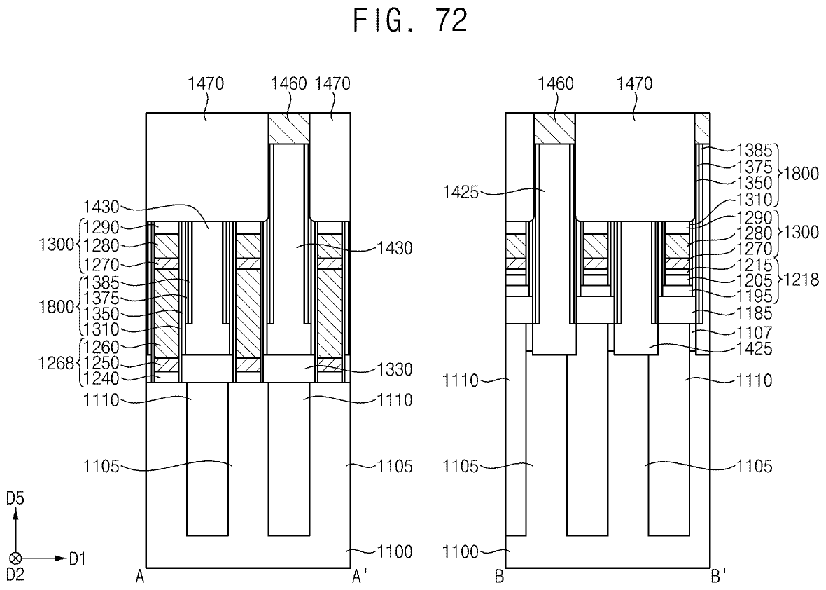

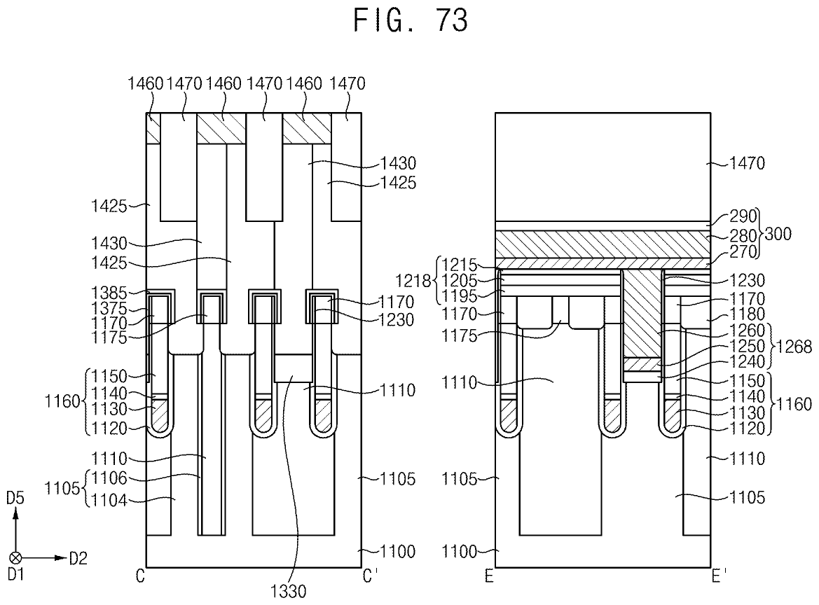

FIGS. 31 to 73 are perspective views, plan views and cross-sectional views illustrating a method of manufacturing a semiconductor device in accordance with example embodiments. Specifically, FIGS. 31 to 33 are the perspective views, FIGS. 34, 37, 40, 43, 46, 49, 52, 55, 62, 65, 68 and 71 are the plan views, each of FIGS. 35, 38, 41, 44, 47, 50, 53, 56, 58, 60, 63, 66, 69 and 72 includes cross-sectional views taken along lines A-A′ and B-B′, respectively, of a corresponding plan view, and each of FIGS. 36, 39, 42, 45, 48, 51, 54, 57, 59, 61, 64, 67, 70 and 73 includes cross-sectional views taken along lines C-C′ and E-E′, respectively, of a corresponding plan view. FIGS. 31 to 33 are perspective views of region Y of FIG. 34.

A method of forming a second active structure illustrated with reference to FIGS. 31 to 33 includes processes substantially the same as or similar to those illustrated with reference to FIGS. 4 to 9, and thus repeated explanations thereof are omitted herein.

Additionally, a method of forming structures illustrated with reference to FIGS. 34 to 73 and FIGS. 27 to 30 includes processes substantially the same as or similar to those illustrated with reference to FIGS. 10 to 26 and FIGS. 1 to 3, and thus repeated explanations thereof are omitted herein.

Referring to FIG. 31, processes substantially the same as or similar to those illustrated with reference to FIGS. 4 to 7 may be performed.

Thus, an etching process may be performed on an upper portion of a second substrate 1100 to form a plurality of second preliminary active patterns 1102 spaced apart from each other in the first direction D1, and each of the second preliminary active patterns 1102 may extend in the third direction D3.

Additionally, a third preliminary isolation layer 42 may be formed on the substrate 1100 and the second preliminary active patterns 1102, and second, third and fourth mask layers 50, 60 and 70 may be sequentially formed on the third preliminary isolation layer 42.

The fourth mask layer 70 may be partially removed to form a tenth opening 77 exposing an upper surface of the third mask layer 60. The tenth opening 77 may extend in the first direction D1, and a plurality of tenth openings 77 may be formed to be spaced apart from each other in the second direction D2.

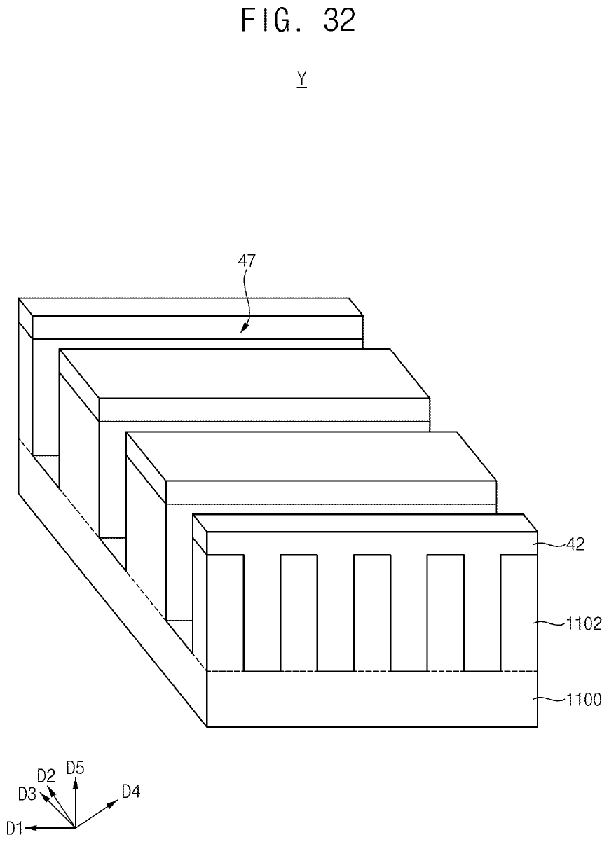

Referring to FIG. 32, processes substantially the same as or similar to those illustrated with reference to FIG. 8 may be performed.

Thus, a portion of the third preliminary isolation layer 42 overlapping the tenth opening 77 in the fifth direction D5 and a portion of the second preliminary active pattern 1102 thereunder may be removed by a dry etching process to form an eleventh opening 47 exposing an upper surface of the second substrate 1100.

The eleventh opening 47 may extend through the second preliminary active patterns 1102 to expose the upper surface of the second substrate 1100. In example embodiments, the eleventh opening 47 may extend in the first direction D1, and a plurality of eleventh openings 47 may be formed to be spaced apart from each other in the second direction D2. Thus, each of the second preliminary active patterns 1102 may be divided into a plurality of second active patterns 1104 spaced apart from each other in the third direction D3 by the eleventh openings 47. In example embodiments, the plurality of second active patterns 1104 may be spaced apart from each other in each of the first and third directions D1 and D3.

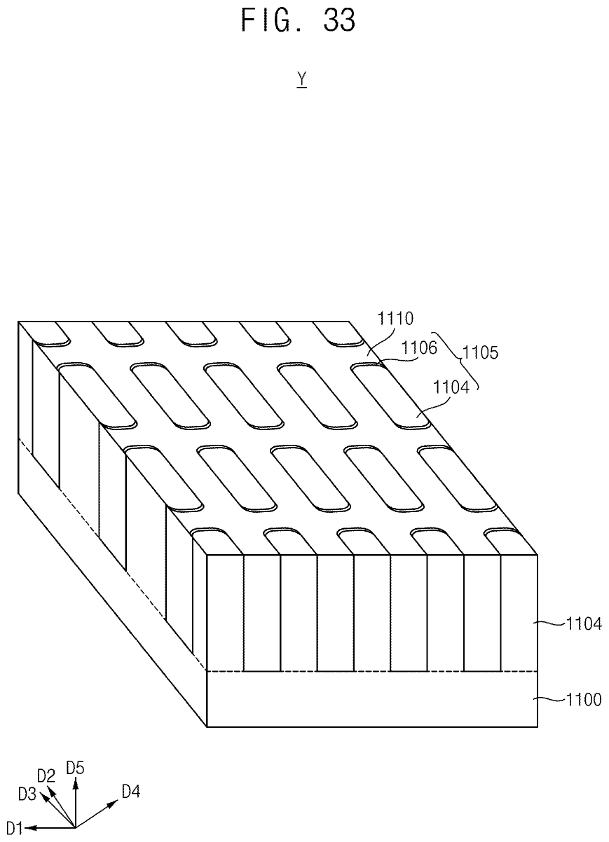

Referring to FIG. 33, processes substantially the same as or similar to those illustrated with reference to FIG. 9 may be performed.

Thus, a SEG process may be performed using a sidewall of the second active pattern 1104 exposed by the eleventh opening 47 to form a second epitaxial pattern 1106 on a portion of the second active pattern 1104 exposed by the eleventh opening 47.

In example embodiments, the second epitaxial pattern 1106 may be formed on a sidewall of each of end portions in the third direction D3 of the second active pattern 1104 exposed by the eleventh opening 47. In some embodiments, the second epitaxial pattern 1106 may also be formed on the upper surface of the second substrate 1100 exposed by the eleventh opening 47, however, in this case, an anisotropic etching process may be further performed on the second epitaxial pattern 1106 so that the second epitaxial pattern 1106 on the upper surface of the second substrate 1100 may be removed.

In an example embodiment, a crystalline orientation of the second epitaxial pattern 1106 may be different from that of the second active pattern 1104, and thus the second epitaxial pattern 1106 may be distinguished from the second active pattern 1104. Alternatively, the crystalline orientation of the second epitaxial pattern 1106 may be substantially the same as that of the second active pattern 1104, and thus the second epitaxial pattern 1106 may not be distinguished from the second active pattern 1104.

The second active pattern 1104 and the second epitaxial pattern 1106 may collectively form a second active structure 1105. In example embodiments, the second active structure 1105 may extend in the third direction D3 to a given length, and a plurality of second active structures 1105 may be spaced apart from each other in each of the first and third directions D1 and D3.

A plurality of second active structures 1105 disposed in the first direction D1 may collectively form a second active structure row, and a plurality of second active structure rows may be disposed in the second direction D2 or in the third direction D3 to form a second active structure array.

A fourth preliminary isolation layer may be formed on the second active structure 1105 and the third preliminary isolation layer 42 to fill the eleventh opening 47, and a planarization process may be performed on the fourth preliminary isolation layer. In example embodiments, the fourth preliminary isolation layer may include substantially the same material as the third preliminary isolation layer 42, and thus may be merged thereto. By the planarization process, a second isolation pattern 1110 may be formed.

The second isolation pattern 1110 may be formed on the second substrate 1100, and may cover opposite sidewalls in the first direction D1 of each of the second active patterns 1104. The second isolation pattern 1110 may also cover a sidewall of the second epitaxial pattern 1106 on the sidewall of each of opposite end portions in the third direction D3 of each of the second active patterns 1104.

Referring to FIGS. 34 to 36, upper portions of the second active structure 1105 and the second isolation pattern 1110 may be removed to form a third recess, and a second gate insulation layer may be formed on an inner wall of the third recess and upper surfaces of the second active structure 1105 and the second isolation pattern 1110.

A third conductive layer may be formed on the second gate insulation layer, an upper portion of the third conductive layer may be removed to form a third conductive pattern 1130, a fourth conductive layer may be formed on the third conductive pattern 1130 and the second gate insulation layer, and an upper portion of the fourth conductive layer may be removed to form a fourth conductive pattern 140.

A second gate mask layer may be formed on the fourth conductive pattern 1140 and the second gate insulation layer, and the second gate mask layer and the second gate insulation layer may be planarized until the upper surfaces of the second active structure 1105 and the second isolation pattern 1110 are exposed to form a second gate mask 1150 and a second gate insulation pattern 1120, respectively.

The second gate insulation pattern 1120, the third and fourth conductive patterns 1130 and 1140 and the second gate mask 1150 in the third recess may collectively form a second gate structure 1160.

In example embodiments, the second gate structure 1160 may extend in the first direction D1, and a plurality of second gate structures 1160 may be spaced apart from each other in the second direction D2. In an example embodiment, two second gate structures 1160 spaced apart from each other in the second direction D2 may be formed at an upper portion of a single second active structure 1105. Hereinafter, a portion of the second active structure 1105 between the two second gate structures 160 may be referred to as a central portion thereof, and a portion of the second active structure 1105 at an opposite side of the central portion of the second active structure 1105 with respect to a corresponding one of the two second gate structures 1160 may be referred to as an end portion thereof.

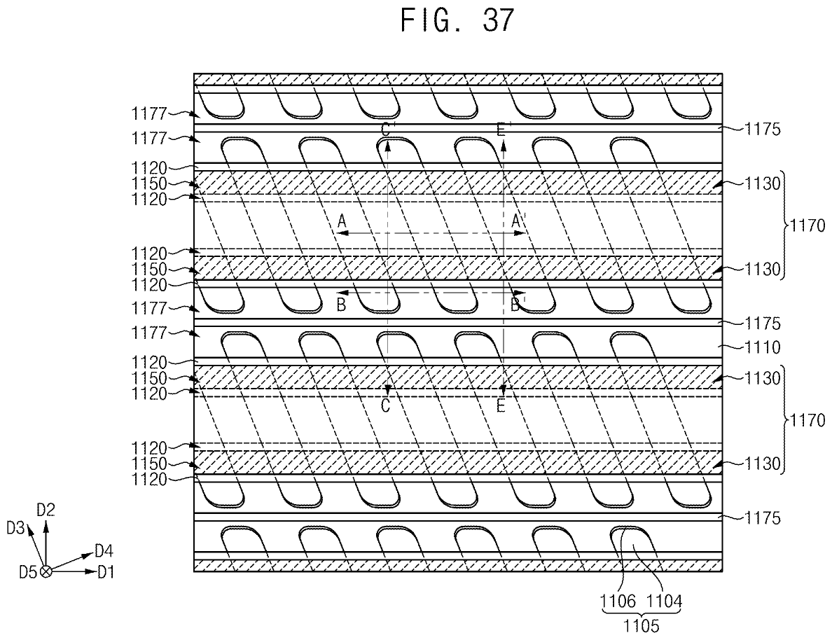

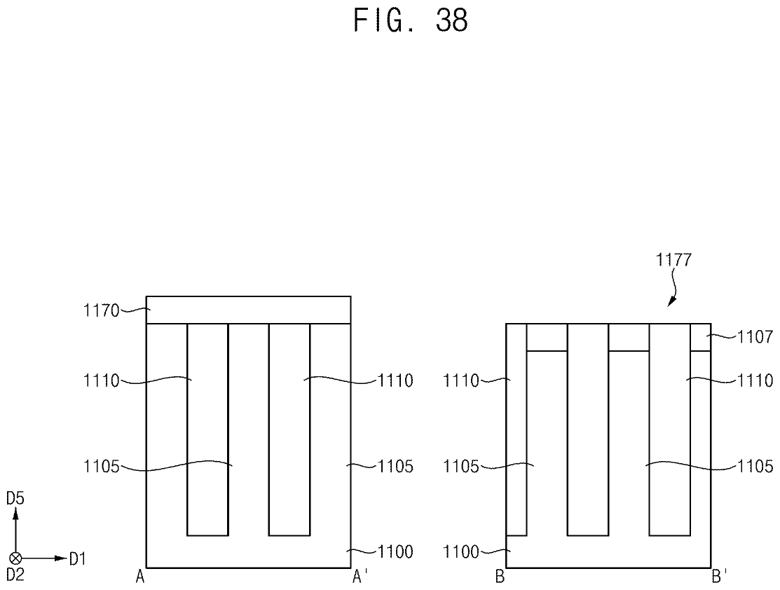

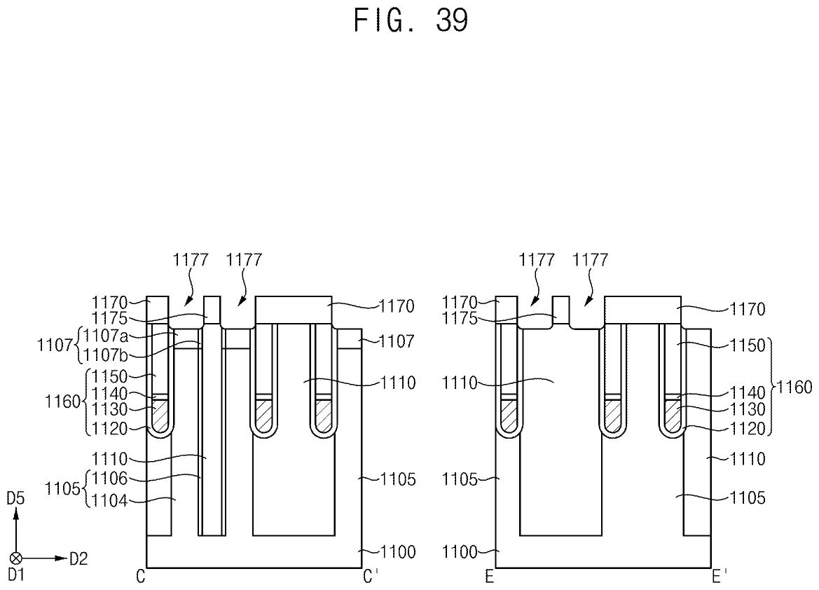

Referring to FIGS. 37 to 39, second and third mold layers 1170 and 1175 may be formed on the second active structure 1105, the second isolation pattern 1110 and the second gate structure 1160, and a twelfth opening 1177 may be formed between the second and third mold layers 1170 and 1175.

In example embodiments, each of the second and third mold layers 1170 and 1175 may extend in the first direction D1, and thus the twelfth opening 1177 may also extend in the first direction D1. The second mold layer 1170 may cover upper surfaces of the two second gate structures 160 extending through the upper portion of the second active structure 1105, and the third mold layer 1175 may cover an upper surface of a portion of the second isolation pattern 1110 between the second active structure rows neighboring in the second direction D2.

In an example embodiment, the second mold layer 1170 may not cover a portion of the second gate insulation pattern 1120 of each of the second gate structures 1160 that is adjacent to the end portion of the second active structure 1105, and the third mold layer 1175 may be spaced apart from the end portion of the second active structure 1105 in the second direction D2.

An etching process using the second and third mold layers 1170 and 1175 as an etching mask may be performed to partially remove the upper portion of second active structure 1105, the upper portion the second isolation pattern 1110 and an upper portion of the second gate insulation pattern 1120 exposed by the twelfth opening 1177, and thus the twelfth opening 1177 may be enlarged downwardly. During the etching process, an upper portion of each end portion of the second active structure 1105 may be removed.

A doping process, for example, a gas phase doping (GPD) process may be performed on the end portions of the second active structure 1105 exposed by the twelfth opening 1177 to form an impurity region structure 1107. The impurity region structure 1107 may include a first impurity region 1107a in the second active pattern 1104 and a second impurity region 1107b in the second epitaxial pattern 1106.

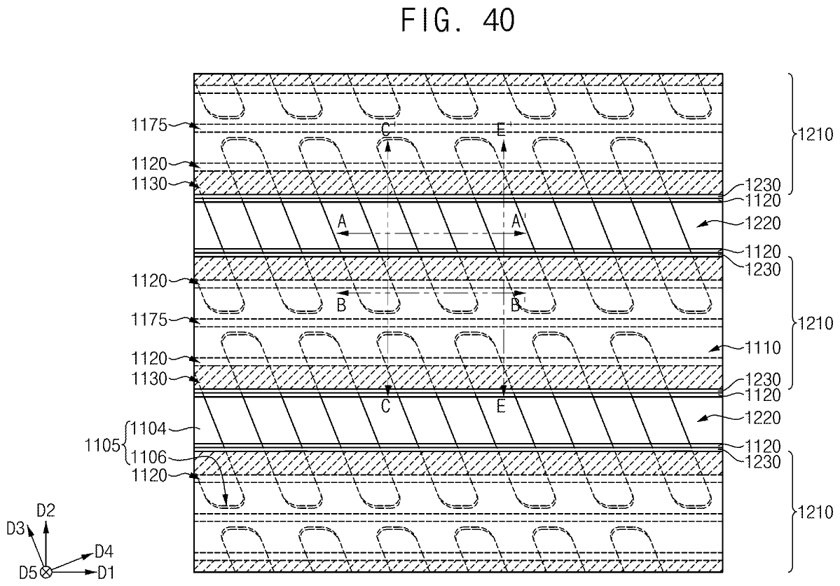

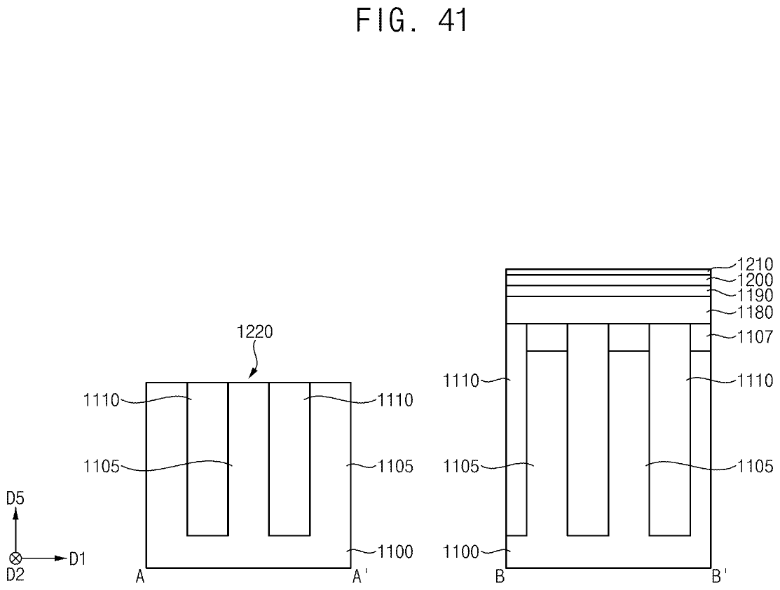

Referring to FIGS. 40 to 42, a fourth mold layer 1180 may be formed on the second active structure 1105, the second isolation pattern 1110, the second gate insulation pattern 1120 and the second and third mold layers 1170 and 1175 to fill the twelfth opening 1177, and a planarization process may be performed on the fourth mold layer 1180.

The fourth mold layer 1180 may be formed in the twelfth opening 1177, and may extend in the first direction D1.

First to third buffer layers 1190, 1200 and 1210 may be sequentially stacked on the second to fourth mold layers 1170, 1175 and 1180 in the fifth direction D5, and a thirteenth opening 1220 may be formed through the second to fourth mold layers 1170, 1175 and 1180 and the second mold layer 1170 thereunder to expose the upper surfaces of the second active structure 1105 and the second isolation pattern 1110.

In example embodiments, the thirteenth opening 1220 may extend in the first direction D1, and may expose a central portion of each of the second active structures 1105 included in the second active structure row, a portion of the second isolation pattern 1110 adjacent thereto in the first direction D1, and a portion of the second gate insulation pattern 1120 adjacent thereto in the second direction D2.

A fifth spacer layer may be formed on the first to third buffer layers 1190, 1200 and 1210, and the second active structure 1105, the second isolation pattern 1110 and the second gate insulation pattern 1120 exposed by the thirteenth opening 1220 and, and an anisotropic etching process may be performed on the fifth spacer layer to form a fifth spacer 1230 on each of sidewalls of the thirteenth opening 1220 in the second direction D2.

Upper portions of the central portion of each of the second active structures 1105 exposed by the thirteenth opening 1220, the portion of the second isolation pattern 1110 adjacent thereto, and the portion of the second gate insulation pattern 120 adjacent thereto may be removed so that the thirteenth opening 1220 may be enlarged downwardly in the fifth direction D5.

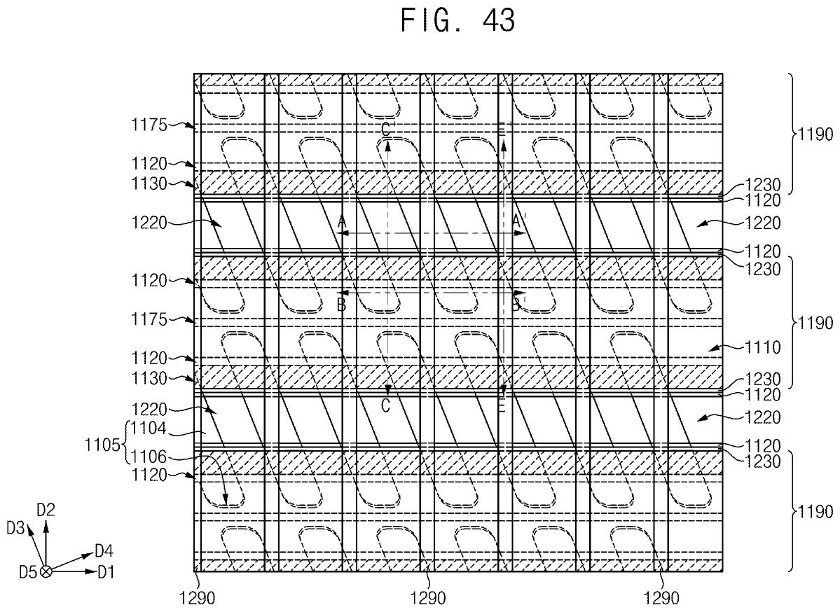

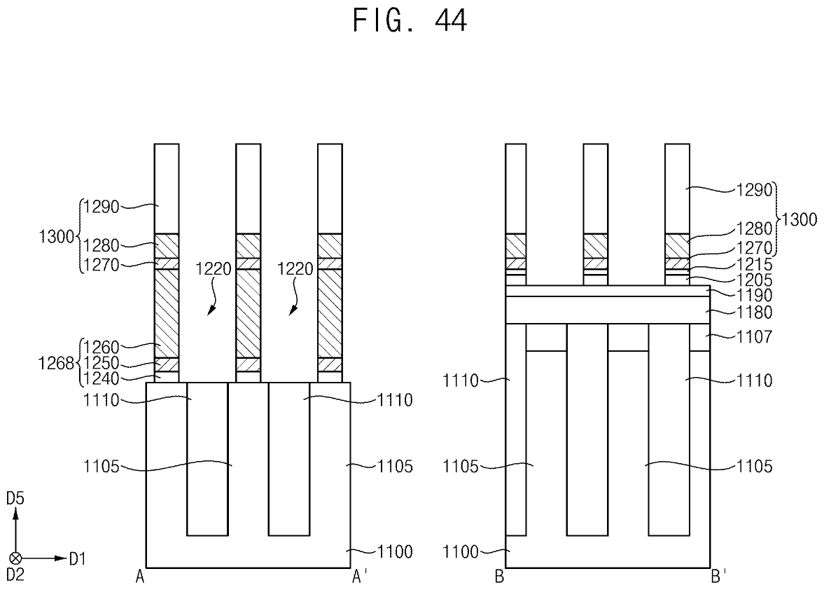

Referring to FIGS. 43 to 45, a second pad layer, an ohmic contact layer and a fourth metal layer may be sequentially formed in the thirteenth opening 1220.

The ohmic contact layer may be formed by forming a third metal layer on the second pad layer and performing a heat treatment process on the third metal layer so that the third metal layer and the second pad layer may be reacted with each other.

A planarization process may be further performed on an upper portion of the fourth metal layer, and thus an upper surface of the fourth metal layer may be substantially coplanar with an upper surface of the third buffer layer 1210.

A third barrier layer, a fifth metal layer and a seventh mask layer may be sequentially stacked on the third buffer layer 1210, the fourth metal layer and the fifth spacer 1230 in the fifth direction D5, the seventh mask layer may be patterned to form a seventh mask 1290, and an etching process using the seventh mask 1290 as an etching mask may be performed to pattern the fifth metal layer, the third barrier layer and the third buffer layer 1210, and furthermore, the fourth metal layer, the ohmic contact layer and the second pad layer may also be patterned.

Accordingly, the second pad layer, the ohmic contact layer and the fourth metal layer may be transformed into a second pad 1240, an ohmic contact pattern 1250 and a fourth metal pattern 1260, respectively, and the second pad 1240, the ohmic contact pattern 1250 and the fourth metal pattern 1260 may collectively form a second contact plug structure 1268. In example embodiments, a plurality of second contact plug structures 1268 may be spaced apart from each other in the thirteenth opening 1220 in the first direction D1.

The third barrier layer and the fifth metal layer may be transformed into a third barrier pattern 1270 and a fifth metal pattern 1280, respectively. The third barrier pattern 1270, the fifth metal pattern 1280 and the seventh mask 1290 sequentially stacked in the fifth direction D5 may collectively form a second bit line structure 1300. In example embodiments, the second bit line structure 1300 may extend in the second direction D2, and a plurality of second bit line structures 1300 may be spaced apart from each other in the first direction D1.

The second bit line structure 1300 may overlap the central portions of the second active structures 1105 disposed in the second direction D2, and the second contact plug structure 1268 may be interposed between the second bit line structure 1300 and each of the second active structures 1105 to electrically connect the second bit line structure 1300 and each of the second active structures 1105 to each other.

The second and the third buffer layers 1200 and 1210 may be patterned to remain as a second buffer 1205 and a third buffer 1215, respectively, under the second bit line structure 1300.

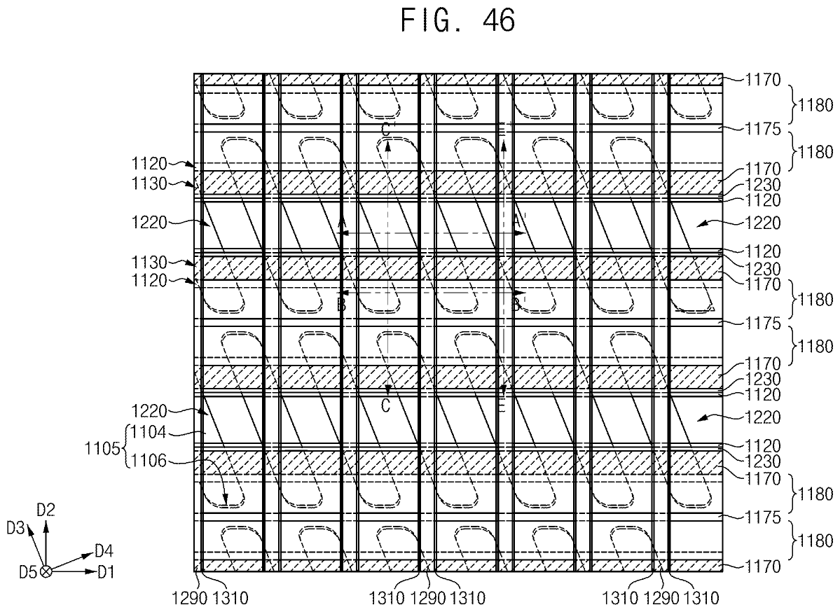

Referring to FIGS. 46 to 48, a sixth spacer layer may be formed on the second bit line structure 1300, the second contact plug structure 1268, the second and third buffers 1205 and 1215, the first buffer layer 1190, the fifth spacer 1230, and on the second active structure 1105, the second isolation pattern 1110 and the second gate insulation pattern 1120 exposed by the thirteenth opening 1220, and an anisotropic etching process may be performed on the sixth spacer layer to form a sixth spacer 1310 on sidewalls of the second bit line structure 1300, the second contact plug structure 1268 and the second and third buffers 1205 and 1215.

An etching process, for example, a dry etching process or a wet etching process may be performed on the first buffer layer 1190 to form a first buffer 1195, and the first buffer 1195 may remain under the second buffer 1205 and the sixth spacer 1310. The first to third buffers 1195, 1205 and 1215 sequentially stacked in the fifth direction D5 may collectively form a buffer structure 1218. In example embodiments, a plurality of buffer structures 1218 may be spaced apart from each other by the second contact plug structure 1268 and the fifth spacer 1230 in the second direction D2 under the second bit line structure 1300.

As the etching process is performed, upper surfaces of portions of the second to fourth mold layers 1170, 1175 and 1180, which may not be overlapped with the second bit line structure 1300 in the fifth direction D5, may be exposed.

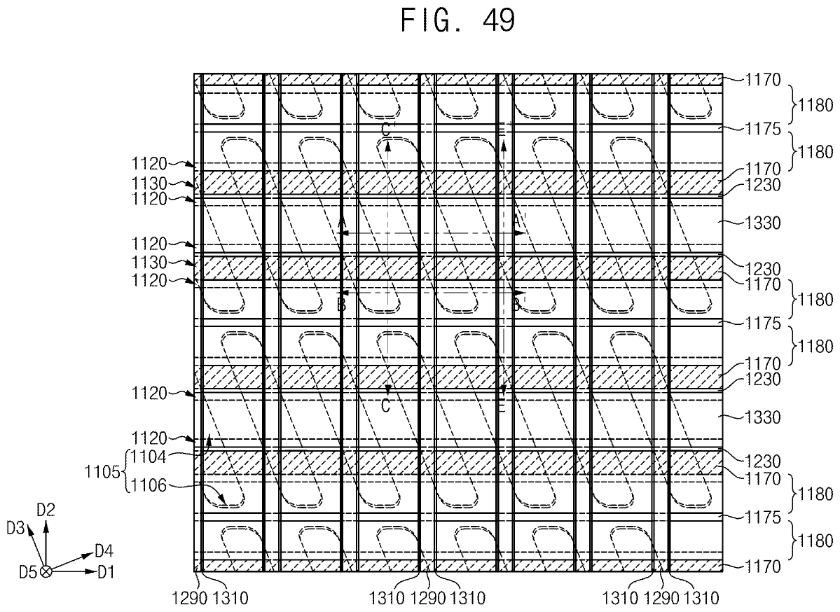

Referring to FIGS. 49 to 51, a filling pattern 1330 may be formed in the thirteenth opening 1220.

In example embodiments, the filling pattern 1330 may be formed by forming a filling layer on the second bit line structure 1300, the sixth spacer 1310, the first buffer 1195, the second to fourth mold layers 1170, 1175 and 1180, the fifth spacer 1230, the second active structure 1105, the second isolation pattern 1110 and the second gate insulation pattern 1120, and performing an etching process on the filling layer.

Thus, a filling pattern 1330 may be formed on upper surfaces of the second active structure 1105, the second isolation pattern 1110 and the second gate insulation pattern 1120 exposed by the thirteenth opening 1220 to contact a sidewall of a lower portion of the sixth spacer 1310 on a sidewall of the second contact plug structure 1268.

In example embodiments, a plurality of filling patterns 1330 may be spaced apart from each other in the first direction D1 by the second contact plug structure 1268 and the lower portion of the sixth spacer 1310 in each of the thirteenth openings 1220. In example embodiments, an upper surface of the filling pattern 1330 may be substantially coplanar with the upper surfaces of the second active structure 1105 and the second isolation pattern 1110.

Referring to FIGS. 52 to 54, an upper portion of the filling pattern 1330 may be removed by, e.g., an etch back process to form a fourteenth opening 1365, a seventh spacer 1350 may be formed on an outer sidewall of the sixth spacer 1310 on each of opposite sidewalls in the first direction D1 of the second bit line structure 1300 and the second contact plug structure 1268, and an etching process may be performed using the second bit line structure 1300, the second contact plug structure 1268 and the sixth and seventh spacers 1310 and 1350 as an etching mask.

Thus, the fourth mold layer 1180 and upper portions of the second active structure 1105 and the second isolation pattern 1110 may be partially removed to form a fifteenth opening 1360. During the etching process, the fourth mold layer 1180 extending in the first direction D1 may be divided into fourth molds 1185 spaced apart from each other in the first direction D1, and each of the fourth molds 1185 may be formed under the buffer structure 1218.

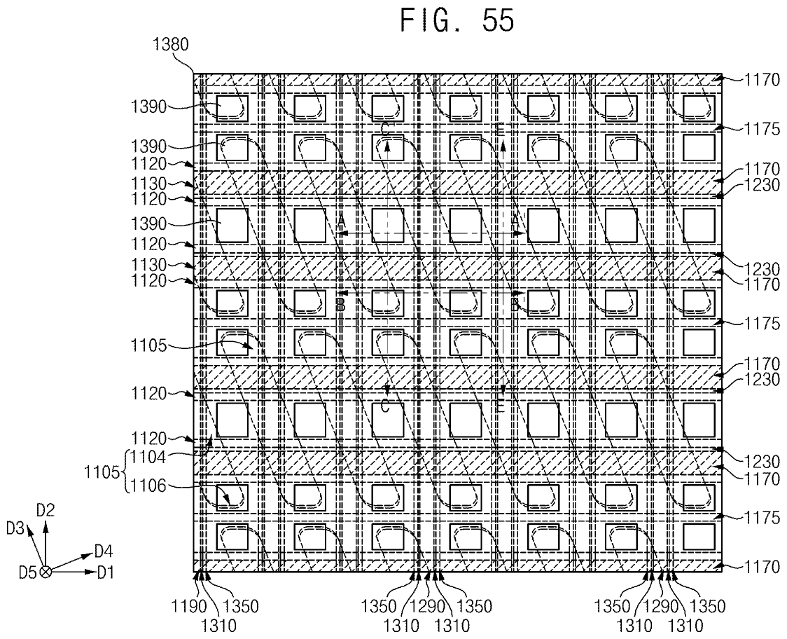

Referring to FIGS. 55 to 57, a third etch stop layer 1370 and an eighth spacer layer 1380 may be sequentially stacked on upper surfaces and sidewalls of the second active structure 1105 and the second isolation pattern 1110 exposed by the fourteenth and fifteenth openings 1365 and 1360, an upper surface of the filling pattern 1330, an upper surface of the second bit line structure 1300, sidewalls of the seventh spacer 1350, the fourth mold 1185, the fifth spacer 1230 and the second gate insulation pattern 1120, and upper surfaces and sidewalls of the second and third mold layers 1170 and 1175.

A second sacrificial layer may be formed on the eighth spacer layer 1380 to fill the fourteenth and fifteenth openings 1365 and 1360 by, e.g., a coating process, and an upper portion of the second sacrificial layer may be removed by, e.g., an etch back process to form a second sacrificial pattern 1390. In an example embodiment, an upper surface of the second sacrificial pattern 1390 may be substantially coplanar with the upper surfaces of the second active structure 1105 and the second isolation pattern 1110, however, the inventive concept may not be limited thereto.

The second sacrificial pattern 1390 may include, e.g., spin-on-hardmask (SOH), amorphous carbon layer (ACL), etc.

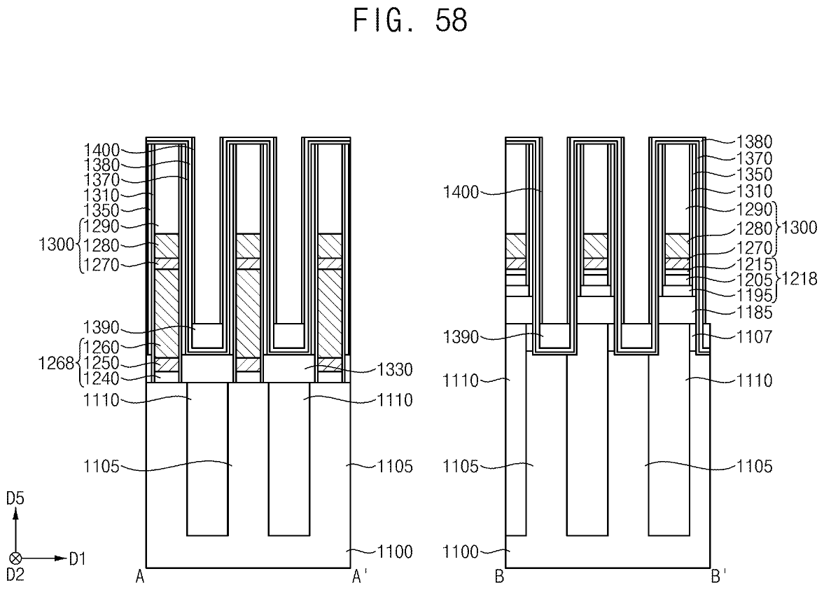

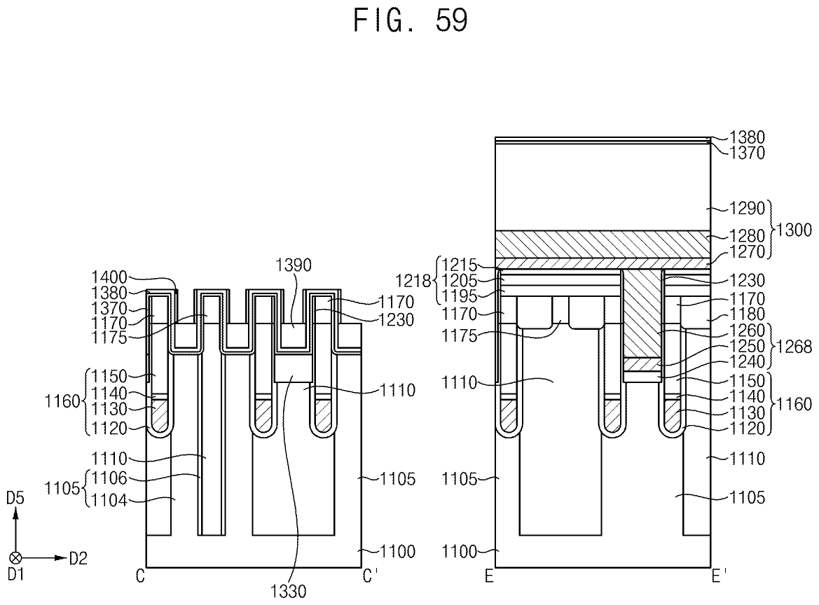

Referring to FIGS. 58 and 59, a third sacrificial layer may be formed on the eighth spacer layer 1380 and the second sacrificial pattern 1390, and may be anisotropically etched to form a third sacrificial pattern 1400 on an upper sidewall of the eighth spacer layer 1380.

The third sacrificial pattern 1400 may include an oxide, e.g., silicon oxide.

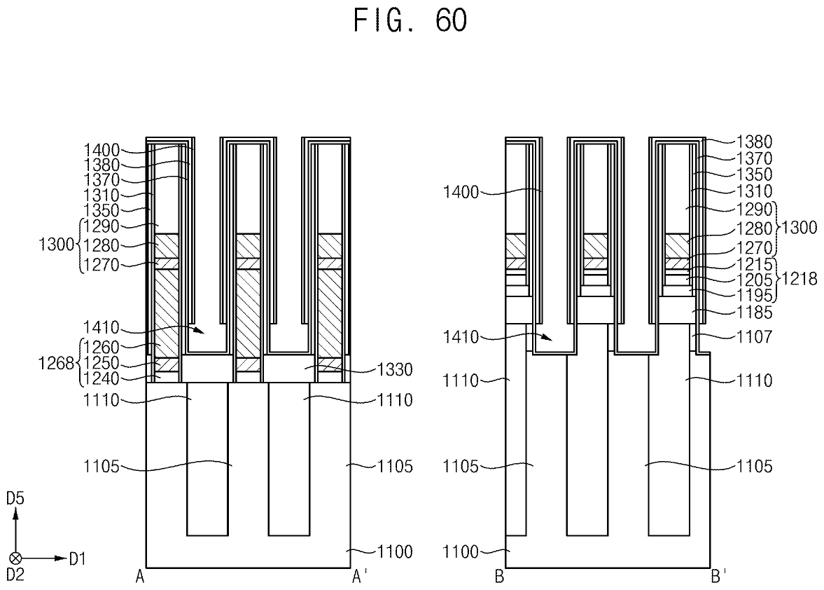

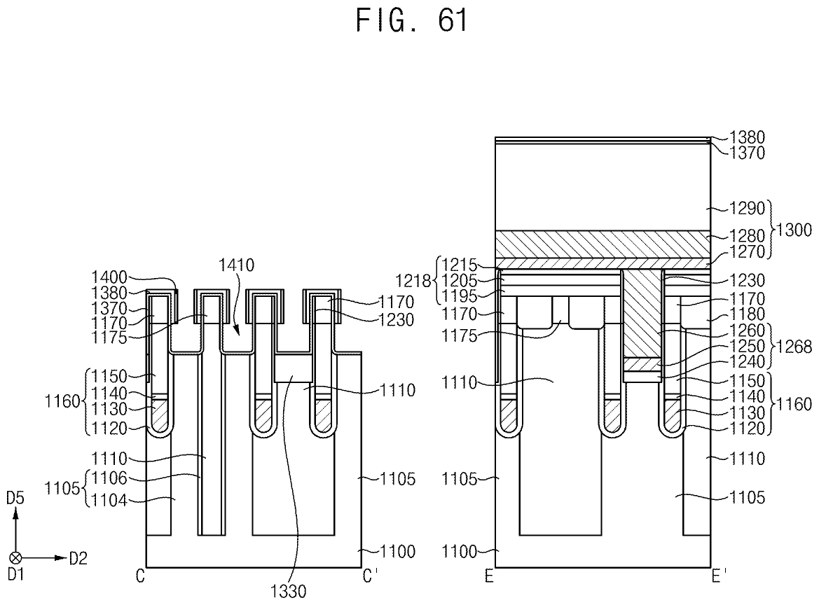

Referring to FIGS. 60 and 61, the second sacrificial pattern 1390 may be removed by, e.g., an ashing process and/or a stripping process to form a sixteenth opening 1410 exposing a surface of a lower portion of the eighth spacer layer 1380.

A lower portion of the eighth spacer layer 1380 exposed by the sixteenth opening 1410 may be additionally removed by a stripping process including a wet etching process using H₃PO₄ to expose a surface of the third etch stop layer 1370.

During the stripping process, the upper surface of the filling pattern 1330 may be covered by the third etch stop layer 1370 not to be removed, and a remaining portion of the eighth spacer layer 1380 may be covered by the third sacrificial pattern 1400 not to be removed.

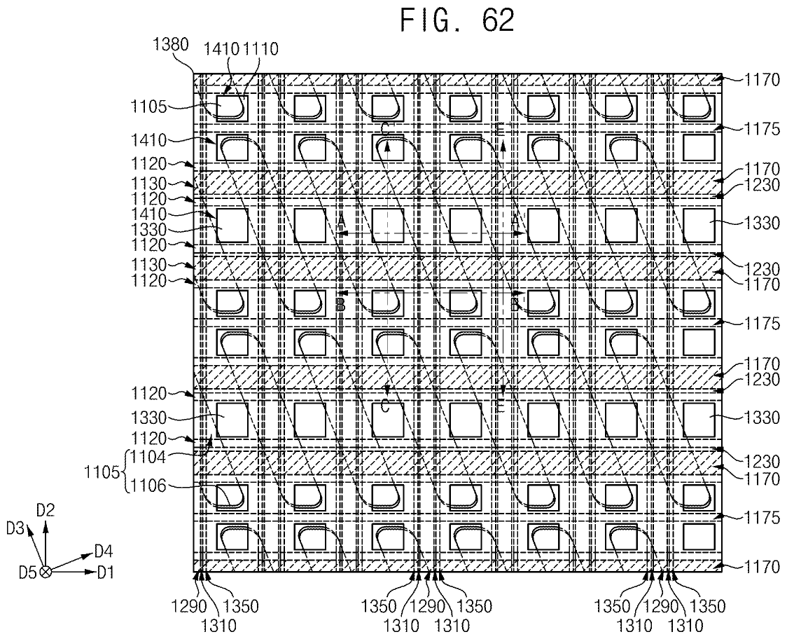

Referring to FIGS. 62 to 64, a lower portion of the third etch stop layer 1370 exposed by the sixteenth opening 1410 may be removed by a stripping process including a wet etching process using, e.g., hydrogen fluoride (HF), and thus the upper surfaces and the sidewalls of the second active structure 1105 and the second isolation pattern 1110 and the upper surface of the filling pattern 1330 may be exposed.

During the stripping process, the third sacrificial pattern 1400 on the sidewall of the eighth spacer layer 1380 may also be removed.

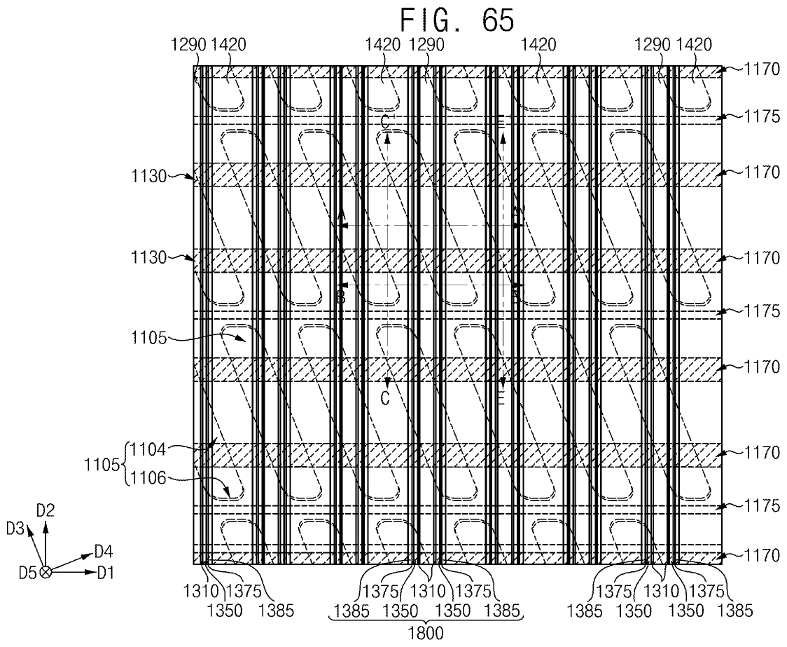

Referring to FIGS. 65 to 67, a cleaning process including a wet etching process may be performed on an inner wall of the sixteenth opening 1410 to remove etching residue, a third contact plug structure layer 1420 may be formed on the second active structure 1105, the second isolation pattern 1110, the filling pattern 1330 and the eighth spacer layer 1380 to fill the sixteenth opening 1410 and a space between the second bit line structures 1300, and a planarization process may be performed on the third contact structure layer 1420 until the upper surface of the second bit line structure 1300 is exposed.

During the planarization process, upper portions of the third etch stop layer 1370 and the eighth spacer layer 1380 on the upper surface of the second bit line structure 1300 may also be removed to form a third etch stop pattern 1375 and an eighth spacer 1385, respectively. Thus, the sixth spacer 1310, the seventh spacer 1350, the third etch stop pattern 1375 and the eighth spacer 1385 may be sequentially stacked on each of opposite sidewalls in the first direction D1 of the second bit line structure 1300, which may collectively form a second spacer structure 1800.

The third contact plug structure layer 1420 may extend in the second direction D2 between neighboring ones of the second bit line structures 1300 in the first direction D1, and a plurality of third contact plug structure layers 1420 may be spaced apart from each other in the first direction D1. The third contact plug structure layer 1420 may contact the upper surfaces of the second active structure 1105, the second isolation pattern 1110 and the filling pattern 1330, a sidewall of a lower portion of the seventh spacer 1350 and a sidewall of the eighth spacer 1385.

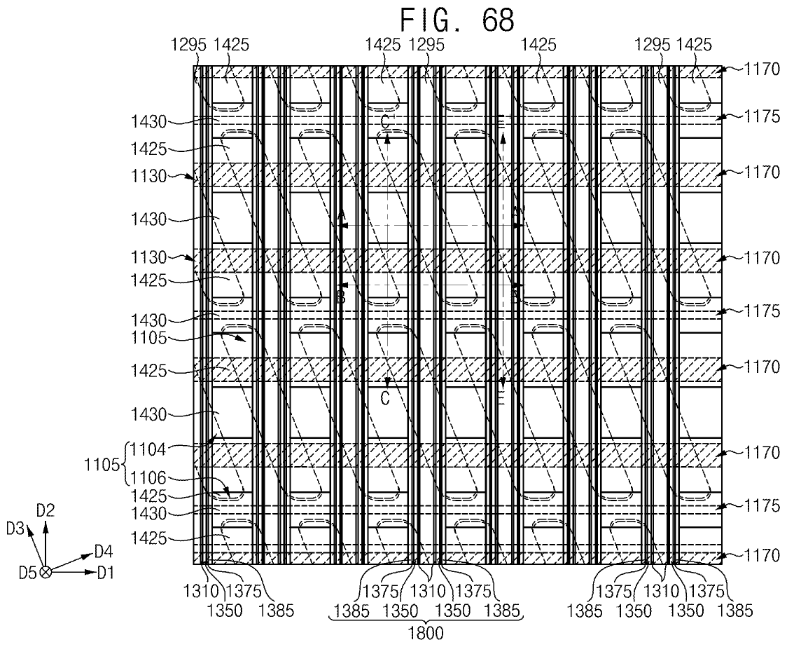

Referring to FIGS. 68 to 70, an etching mask having a seventeenth opening extending in the first direction D1 may be formed on the second bit line structure 1300, the second spacer structure 1800 and the third contact plug structure layer 1420, and the third contact plug structure layer 1420 may be etched using the etching mask to form an eighteenth opening.

In example embodiments, the seventeenth opening may overlap in the fifth direction D5 the central portions of the second active structures 1105 disposed in the first direction D1 and the third mold layer 1175, and thus the eighteenth opening may expose the upper surface of the filling pattern 1330 and an upper surface of a portion of the eighth spacer 1385 on the third mold layer 1175.

By the etching process, the second contact plug structure layer 1420 extending in the second direction D2 may be divided into a plurality of second contact plug structures 1425 spaced apart from each other in the second direction D2, and each of the second contact plug structures 1425 may contact an upper surface of the end portion of the second active structure 1105.

That is, each of the third contact plug structures 1425 may contact the upper surfaces of the end portion in the third direction D3 of the second active pattern 1104 included in the second active structure 1105 and the second epitaxial pattern 1106 on the sidewall thereof, and as the second active structure 1105 includes the second epitaxial pattern 1106, the third contact plug structure 1425 may contact the second active structure 1105 at an increased area so as to reduce a contact resistance therebetween.

A second fence pattern 1430 may be formed to fill the eighteenth opening.

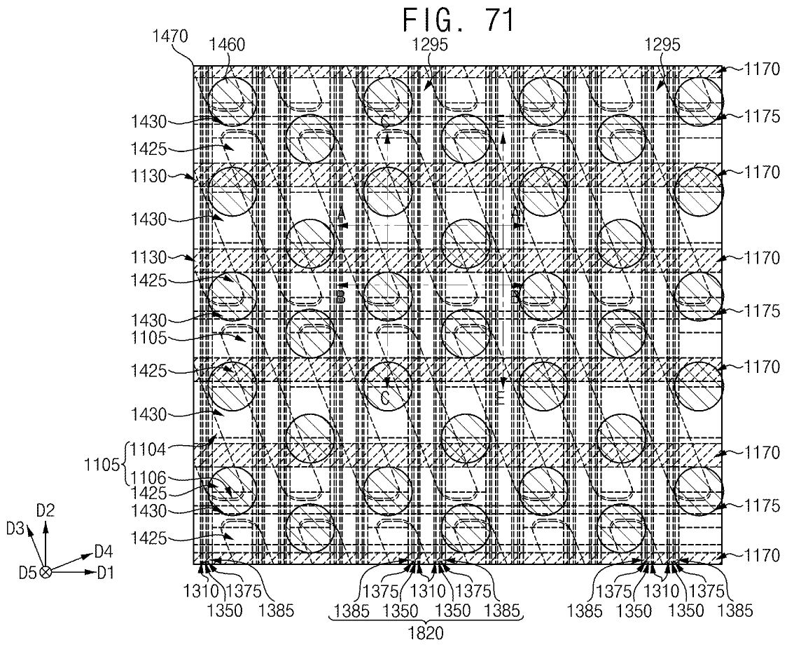

Referring to FIGS. 71 to 73, after forming a landing pad layer on the second bit line structure 1300, the second spacer structure 1800, the third contact plug structure 1425 and the second fence pattern 1430, the landing pad layer, the second bit line structure 1300, the second spacer structure 1800, the third contact plug structure 1425 and the second fence pattern 1430 may be partially removed to form a fourth recess, and an eighth insulation pattern 1470 may be formed to fill the fourth recess.

Thus, the landing pad layer may be divided into a plurality of landing pads 1460 spaced apart from each other in each of the first and second directions D1 and D2, and each of the landing pads 1460 may contact an upper surface of the third contact plug structure 1425. In example embodiments, the landing pads 1460 may be disposed in a honeycomb pattern in a plan view. Alternatively, the landing pads 1460 may be disposed in a lattice pattern in a plan view.

Referring back to FIGS. 27 to 30, a second lower electrode 1480 may be formed on the landing pad 1460, a second dielectric layer 1490 may be formed on the second lower electrode 1480 and the eighth insulation pattern 1470, and a second upper electrode 1500 may be formed on the second dielectric layer 1490.

The second lower electrode 1480, the second dielectric layer 1490 and the second upper electrode 1500 may collectively form a second capacitor 1510.

By the above processes, the semiconductor device may be manufactured.

In the method of manufacturing the semiconductor device in accordance with example embodiments, an upper portion of a substrate may be partially removed to form preliminary active patterns. Each of the preliminary active patterns may extend in a first direction parallel to an upper surface of the substrate, and the preliminary active patterns may be spaced apart from each other in a second direction parallel to the upper surface of the substrate and crossing the first direction. A first preliminary isolation layer may be formed on the substrate and the preliminary active patterns. The first preliminary isolation layer and the preliminary active patterns may be partially removed to form at least one first opening exposing an upper surface of the substrate, and to divide each of the preliminary active patterns into active patterns. A selective epitaxial growth (SEG) process may be performed to form an epitaxial pattern on a sidewall in the first direction of each of the active patterns exposed by the at least one first opening. Each of the active patterns and the epitaxial pattern on the sidewall thereof may form an active structure. A gate structure may be formed in a recess extending through a portion of the active structure. A bit line structure may be formed on a central portion in the first direction of the active structure. A contact plug structure may be formed on each of end portions in the first direction of the active structure. A capacitor may be formed on the contact plug structure.

In example embodiments, when the first preliminary isolation layer and the preliminary active patterns are partially removed to form the at least one first opening exposing the upper surface of the substrate, first, second and third mask layers may be sequentially formed on the first preliminary isolation layer. The third mask layer may be partially removed to form a second opening through the third mask layer. The second opening may overlap the at least one first opening in a vertical direction perpendicular to the upper surface of the substrate. A dry etching process may be performed on the first to third mask layers, the first preliminary isolation layer and the preliminary active patterns.

In example embodiments, when the upper portion of the substrate is partially removed to form the preliminary active patterns, a recess extending in the first direction between the preliminary active patterns may be formed. When the first preliminary isolation layer is formed on the substrate and the preliminary active patterns, the first preliminary isolation layer may be formed to fill the recess.

In example embodiments, after performing the selective epitaxial growth (SEG) process to form the epitaxial pattern, an anisotropic etching process may be performed on the epitaxial pattern.

In example embodiments, after performing the selective epitaxial growth (SEG) process to form the epitaxial pattern, a second preliminary isolation layer may be formed on the substrate and the first preliminary isolation layer to fill the at least one first opening. A planarization process may be performed on the first and second preliminary isolation layers until upper surfaces of the active patterns are exposed to form an isolation pattern.

In example embodiments, the first and second preliminary isolation layers may include the same material so as to be merged with each other.

In example embodiments, the at least one first opening may include a plurality of first openings spaced apart from each other in each of the first and second directions.

In example embodiments, the at least one first opening may include a plurality of first openings spaced apart from each other in a third direction parallel to the upper surface of the substrate and perpendicular to the second direction, and each of the plurality of first openings may extend in the second direction.

In example embodiments, a crystalline orientation of the epitaxial pattern may be the same as a crystalline orientation of each of the active patterns.

In example embodiments, a crystalline orientation of the epitaxial pattern may be different from a crystalline orientation of each of the active patterns.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
at least one active structure including:
an active pattern on a substrate, the active pattern extending in a first direction parallel to an upper surface of the substrate; and
an epitaxial pattern on a sidewall of each of opposite end portions in the first direction of the active pattern, a lowermost surface of the epitaxial pattern being substantially coplanar with a lower surface of the active pattern, and the epitaxial pattern including a single crystalline semiconductor material;
a gate structure in a recess extending through a portion of an upper portion of the at least one active structure;
a bit line structure on a central portion of the at least one active structure in the first direction;
a contact plug structure on each of the opposite end portions of the at least one active structure; and
a capacitor on the contact plug structure.

2. The semiconductor device according to claim 1, wherein the active pattern includes first sidewalls opposite to each other in the first direction, and second sidewalls opposite to each other in a second direction parallel to the upper surface of the substrate and crossing the first direction, and
wherein the epitaxial pattern is disposed on each of the first sidewalls of the active pattern.

3. The semiconductor device according to claim 2, wherein each of the first sidewalls of the active pattern has a rounded shape in a plan view, and
wherein each of the second sidewalls of the active pattern has a shape of a line extending in the first direction in a plan view.

4. The semiconductor device according to claim 1, wherein the epitaxial pattern includes a single crystalline semiconductor material substantially the same as that of the active pattern.

5. The semiconductor device according to claim 4, wherein a crystalline orientation of the epitaxial pattern is substantially the same as a crystalline orientation of the active pattern.

6. The semiconductor device according to claim 4, wherein a crystalline orientation of the epitaxial pattern is different from a crystalline orientation of the active pattern.

7. The semiconductor device according to claim 1, wherein the at least one active structure includes a plurality of active structures spaced apart from each other in a second direction parallel to the upper surface of the substrate and crossing the first direction, and
wherein the plurality of active structures are arranged in a zigzag pattern in the second direction in a plan view.

8. The semiconductor device according to claim 7, wherein a crystalline orientation of the epitaxial pattern included in a first active structure among the plurality of active structures is different from a crystalline orientation of the active pattern included in the first active structure.

9. The semiconductor device according to claim 7, wherein a crystalline orientation of the epitaxial pattern included in a first active structure among the plurality of active structures is different from a crystalline orientation of the active pattern included in a second active structure among the plurality of active structures.

10. The semiconductor device according to claim 1, wherein the at least one active structure includes a plurality of active structures spaced apart from each other in a second direction parallel to the upper surface of the substrate and having an acute angle with respect to the first direction, and
wherein respective end portions in the first direction of the plurality of active structures corresponding to each other are aligned with each other in the second direction.

11. The semiconductor device according to claim 10, wherein a crystalline orientation of the epitaxial pattern included in a first active structure among the plurality of active structures is different from a crystalline orientation of the active pattern included in the first active structure.

12. The semiconductor device according to claim 10, wherein a crystalline orientation of the epitaxial pattern included in a first active structure among the plurality of active structures is different from a crystalline orientation of the active pattern included in a second active structure among the plurality of active structures.

13. A semiconductor device comprising:
active structures including:
active patterns on a substrate, each of the active patterns extending in a first direction parallel to an upper surface of the substrate and including first sidewalls opposite to each other in the first direction and second sidewalls opposite to each other in a second direction parallel to the upper surface of the substrate and perpendicular to the first direction, each of the first sidewalls having a curved shape and each of the second sidewalls having a shape of a line extending in the first direction in a plan view, and the active patterns being disposed in a third direction parallel to the upper surface of the substrate and having an acute angle with respect to each of the first and second directions; and
epitaxial patterns on the first sidewalls, respectively, of each of the active patterns;
a gate structure in a recess respectively extending through portions of upper portions of the active structures;
a bit line structure on a central portion of each of the active structures in the first direction;
a contact plug structure on each of opposite end portions in the first direction of each of the active structures; and
a capacitor on the contact plug structure,
wherein the epitaxial patterns on the first sidewalls, respectively, of one of the active patterns do not overlap each other in the third direction.

14. The semiconductor device according to claim 13, wherein the epitaxial patterns include a single crystalline semiconductor material substantially the same as that of the active patterns.

15. The semiconductor device according to claim 14, wherein a crystalline orientation of at least one of the epitaxial patterns is different from that of the active patterns.

16. The semiconductor device according to claim 13, wherein respective end portions in the first direction of the active patterns disposed in the third direction are aligned with each other in the third direction.

17. A semiconductor device comprising:
an active structure including:
an active pattern on a substrate, the active pattern extending in a first direction parallel to an upper surface of the substrate and including first sidewalls opposite to each other in the first direction and second sidewalls opposite to each other in a second direction parallel to the upper surface of the substrate and perpendicular to the first direction, and each of the first sidewalls having a curved shape and each of the second sidewalls having a shape of a line extending in the first direction in a plan view; and
an epitaxial pattern on each of the first sidewalls of the active pattern, a lowermost surface of the epitaxial pattern being substantially coplanar with a lower surface of the active pattern, and the epitaxial pattern including a single crystalline semiconductor material;
an isolation pattern disposed on the substrate and covering the second sidewalls of the active pattern and a sidewall of the epitaxial pattern;
a gate structure in a recess extending through a portion of an upper portion of the active structure;
a bit line structure on a central portion of the active structure in the first direction;
a contact plug structure on each of opposite end portions in the first direction of the active structure; and
a capacitor on the contact plug structure.

18. The semiconductor device according to claim 17, wherein a lower surface of the isolation pattern is substantially coplanar with the lowermost surface of the epitaxial pattern.

19. The semiconductor device according to claim 17, wherein the epitaxial pattern includes a single crystalline material substantially the same as that of the active pattern.

20. The semiconductor device according to claim 17, wherein a crystalline orientation of the epitaxial pattern is different from that of the active pattern.
